(19) United States
(12) Patent Application Publication
(10) Pub. No.: US 2025/0142893 A1
(43) Pub. Date: May 1, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Hsin-Che CHIANG, Taipei City (TW); Wei-Chih KAO, Taipei (TW); Ju-Li HUANG, Nantou County (TW); Jeng-Ya YEH, New Taipei City (TW); Mu-Chi CHIANG, Hsinchu (TW); Jhon-Jhy LIAW, Zhudong Township (TW)

(21) Appl. No.: 18/498,293

(22) Filed: Oct. 31, 2023

(51) Int. Cl. H01L 29/786; H01L 29/06; H01L 29/423; H01L 29/66; H01L 29/775

(52) U.S. Cl. CPC H10D 30/6757; H10D 30/014; H10D 30/031; H10D 30/43; H10D 30/6735; H10D 62/121; H10D 64/017

(57) ABSTRACT

Semiconductor structures and methods for manufacturing the same are provided. The semiconductor structure includes first nanostructures formed over a substrate along a first direction, and second nanostructures formed over the substrate along the first direction. The semiconductor structure includes a first gate structure formed over the first nanostructures along a second direction, and a second gate structure formed over the second nanostructures along the second direction. The semiconductor structure also includes a dielectric wall structure between the first gate structure and the second gate structure along the second direction. The semiconductor structure also includes a dielectric strip structure formed along the second direction. The dielectric strip structure includes a protruding portion which is lower than a bottom surface of a bottommost first nanostructure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3F-1 illustrate cross-sectional representations of various stages of manufacturing the semiconductor structure shown along line A-A′ in FIG. 1E and in FIG. 2, in accordance with some embodiments.

FIGS. 3A-2 to 3F-2 illustrate cross-sectional representations of various stages of manufacturing the semiconductor structure shown along line B-B′ in FIG. 1E and in FIG. 2, in accordance with some embodiments.

FIGS. 3A-3 to 3F-3 illustrate cross-sectional representations of various stages of manufacturing the semiconductor structure shown along line C₁-C₁′ in FIG. 1E and in FIG. 2, in accordance with some embodiments.

FIG. 4 shows a top-view representation of the semiconductor structure, in accordance with some embodiments.

FIGS. 5A-1 to 5J-1 illustrate cross-sectional representations of various stages of manufacturing the semiconductor structure shown along line E-E′ in FIG. 4, in accordance with some embodiments.

FIGS. 5A-2 to 5J-2 illustrate cross-sectional representations of various stages of manufacturing the semiconductor structure shown along line F-F′ in FIG. 4, in accordance with some embodiments.

FIGS. 5A-3 to 5J-3 illustrate cross-sectional representations of various stages of manufacturing the semiconductor structure shown along line G-G′ in FIG. 4, in accordance with some embodiments.

FIGS. 5A-4 to 5J-4 illustrate cross-sectional representations of various stages of manufacturing the semiconductor structure shown along line H-H′ in FIG. 4, in accordance with some embodiments

FIG. 6 shows a top-view representation of the semiconductor structure after forming the first gate structure and the second gate structure, in accordance with some embodiments.

FIG. 7 illustrates a cross-sectional representation of a semiconductor structure, in accordance with some embodiments.

FIG. 8 illustrates a cross-sectional representation of a semiconductor structure, in accordance with some embodiments.

FIG. 9 illustrates a cross-sectional representation of a semiconductor structure, in accordance with some embodiments.

FIG. 10 shows a top-view representation of the semiconductor structure after forming the first gate structure and the second gate structure, in accordance with some embodiments.

FIG. 11 illustrates a cross-sectional representation of a semiconductor structure, in accordance with some embodiments.

FIG. 12 illustrates a cross-sectional representation of a semiconductor structure, in accordance with some embodiments.

FIG. 13 illustrates a cross-sectional representation of a semiconductor structure, in accordance with some embodiments.

FIG. 14 illustrates a cross-sectional representation of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a first fin structure and a second fin structure formed over an isolation structure over a substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction). The dielectric strip structure is formed along the second direction (e.g. y-axis), and the dielectric wall structure is parallel with the dielectric strip structure. The dielectric strip structure has protruding portions lower than the bottom surface of the isolation structure. The dielectric wall structure is between the first gate structure and the second gate structure. The dielectric strip structure and the dielectric wall structure are formed by using the same mask, and therefore the fabrication time and cost are reduced.

The dummy gate dielectric layer is between the dielectric wall structure and the first fin structure. Since one side of the nanostructure is in direct contact with the dummy gate dielectric layer, the effective width (W_{eff}) of nanostructure (or channel layer) is reduced. When the effective width (W_{eff}) of nanostructure (or channel layer) is reduced, the current of the semiconductor structure can be reduced for power efficiency. Therefore, the performance of the semiconductor structure is improved. The source/drain (S/D) structure or region(s) may refer to a source or a drain, individually or collectively dependent upon the context.

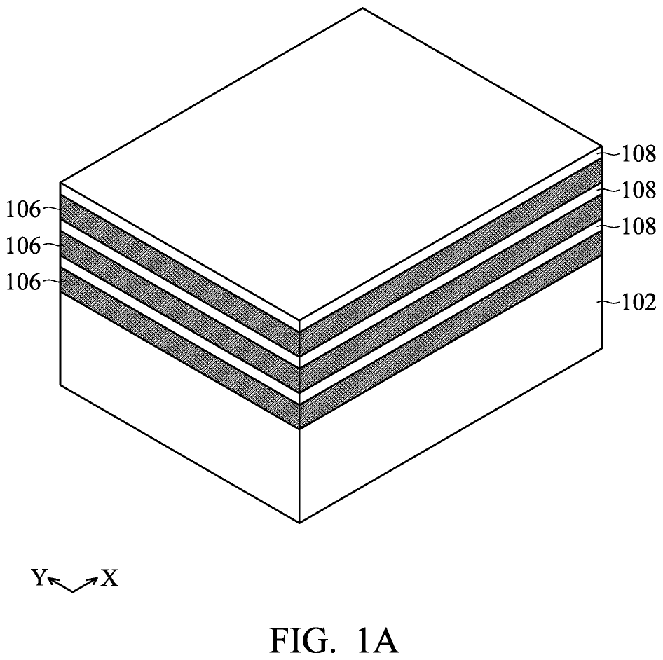

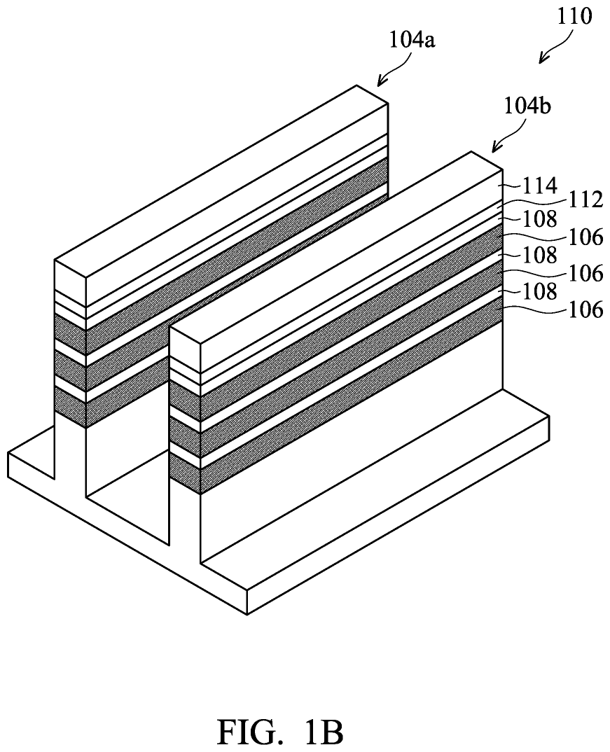

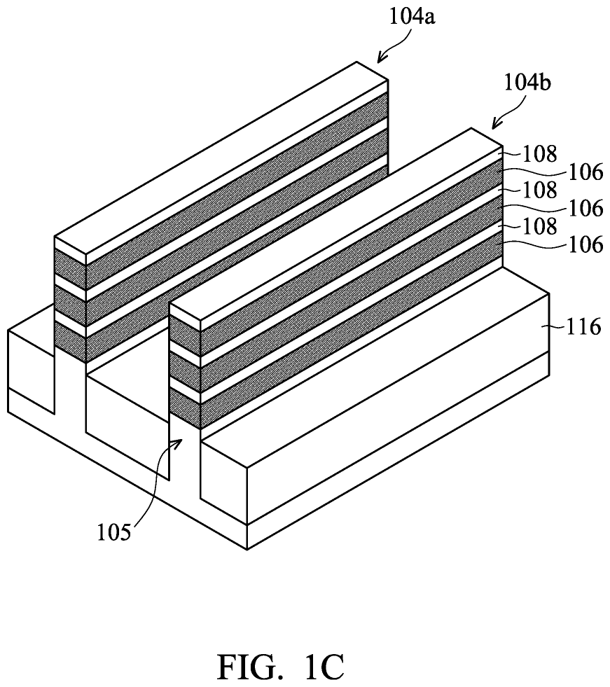

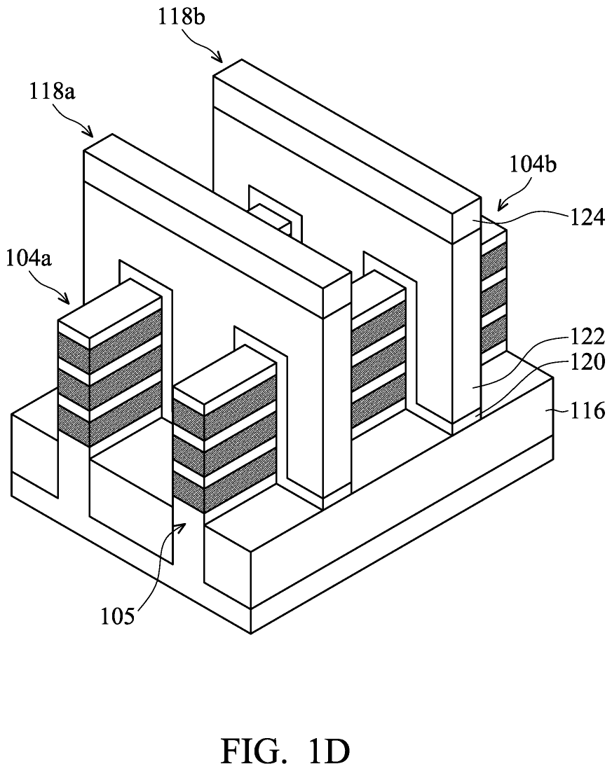

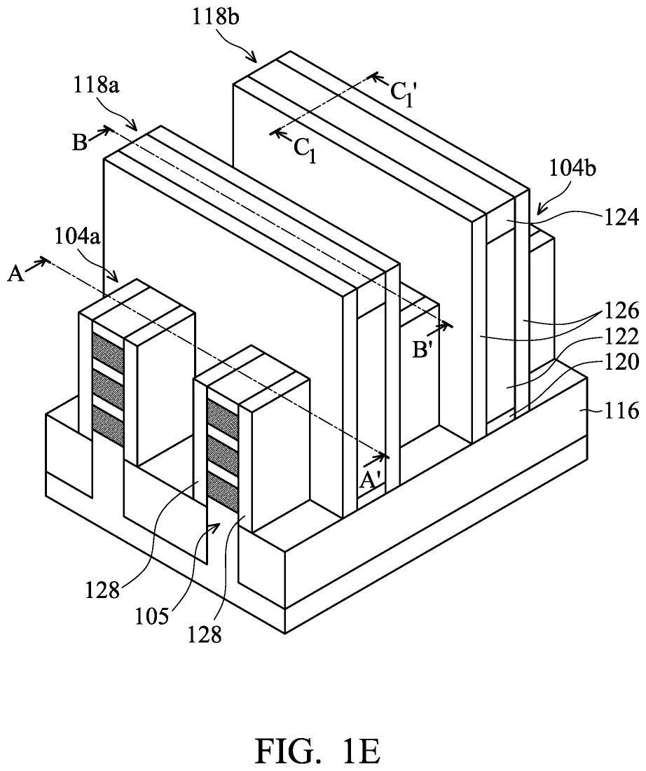

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, first dummy gate structure 118a and second dummy gate structure 118b are formed across the first fin structure 104a and the second fin structure 104b and extend over the isolation structure 116, in accordance with some embodiments. The first dummy gate structure 118a and the second dummy gate structure 118b may be used to define the source/drain (S/D) regions and the channel regions of the resulting semiconductor structure 100a.

In some embodiments, each of the first dummy gate structure 118a and each of the second dummy gate structure 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, the hard mask layers 124 are formed over the first dummy gate structure 118a and the second dummy gate structure 118b. In some embodiments, the hard mask layers 124 include multiple layers, such as an oxide layer and a nitride layer. In some embodiments, the oxide layer is silicon oxide, and the nitride layer is silicon nitride.

The formation of the first dummy gate structure 118a and the second dummy gate structure 118b may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structure 118.

Next, as shown in FIG. 1E, after the first dummy gate structure 118a and the second dummy gate structure 118b are formed, gate spacer layers 126 are formed along and covering opposite sidewalls of the dummy gate structure 118 and fin spacer layers 128 are formed along and covering opposite sidewalls of the source/drain regions of the first fin structure 104a and the second fin structure 104b, in accordance with some embodiments.

The gate spacer layers 126 may be configured to separate source/drain (S/D) structures from the first dummy gate structure 118a, the second dummy gate structure 118b and support the first dummy gate structure 118a, the second dummy gate structure 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

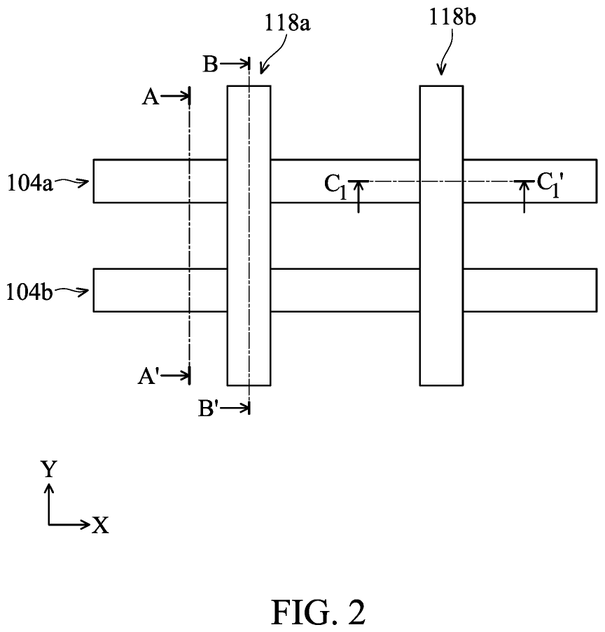

FIG. 2 shows a top-view representation of the semiconductor structure 100a, in accordance with some embodiments.

As shown in FIG. 2, the first fin structure 104a is formed along a first direction (e.g. X-axis), and the second fin structure 104b is formed along the first direction (e.g. X-axis). The first dummy gate structure 118a and the second dummy gate structure 118b are formed along a second direction (e.g. Y-axis). The first dummy gate structure 118a and the second dummy gate structure 118b are formed across the first fin structure 104a and the second fin structure 104b.

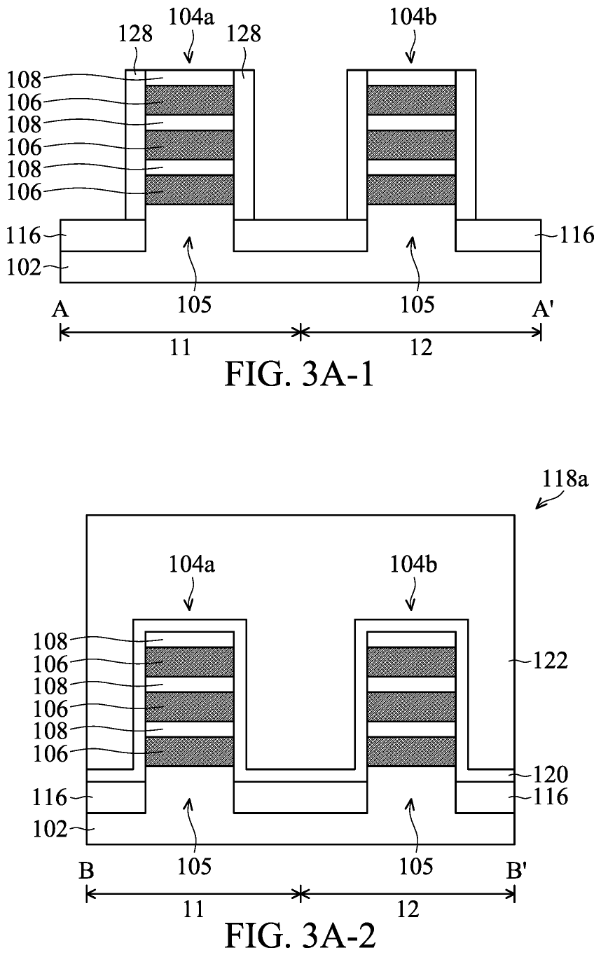

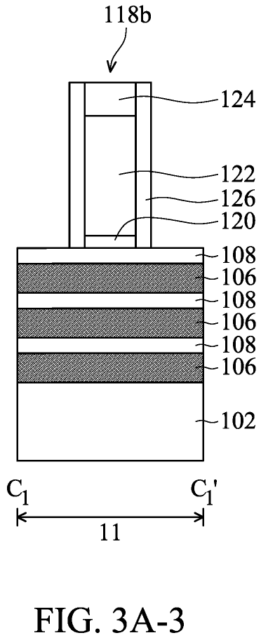

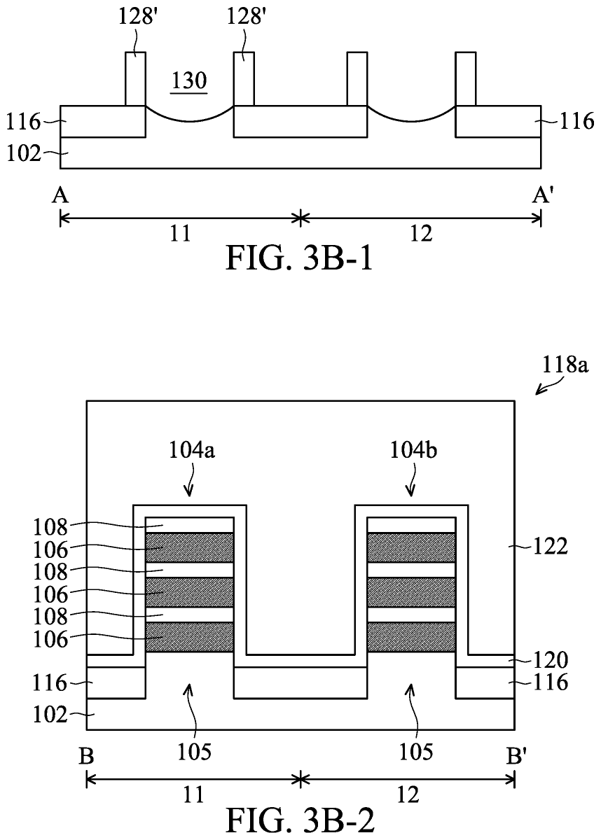

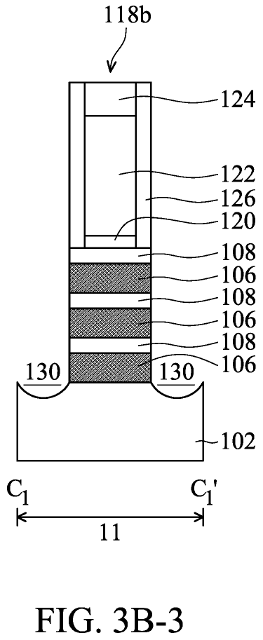

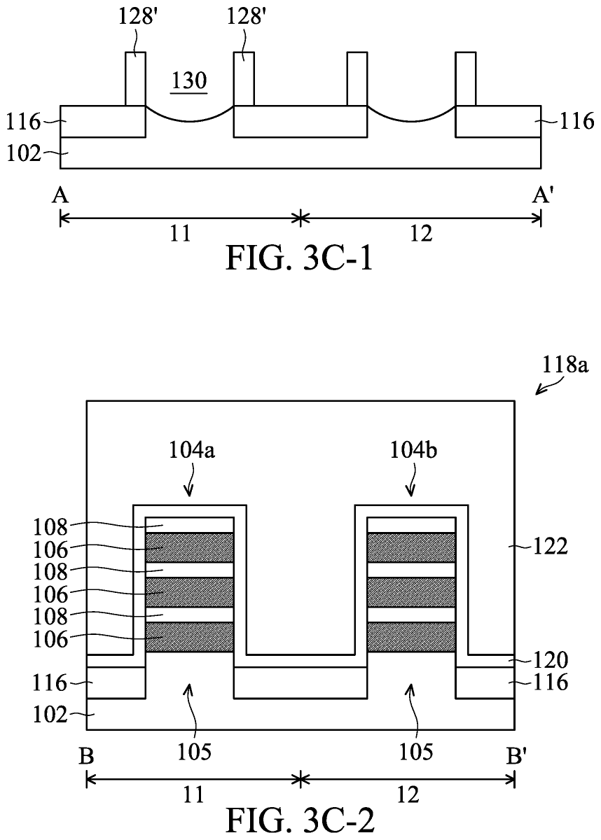

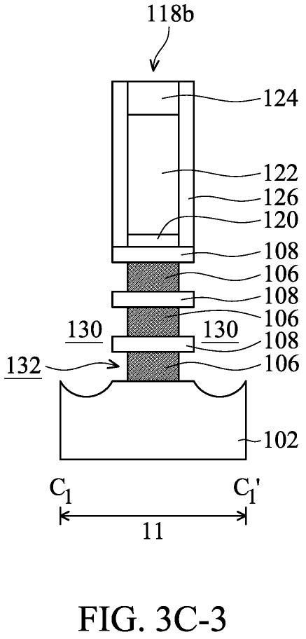

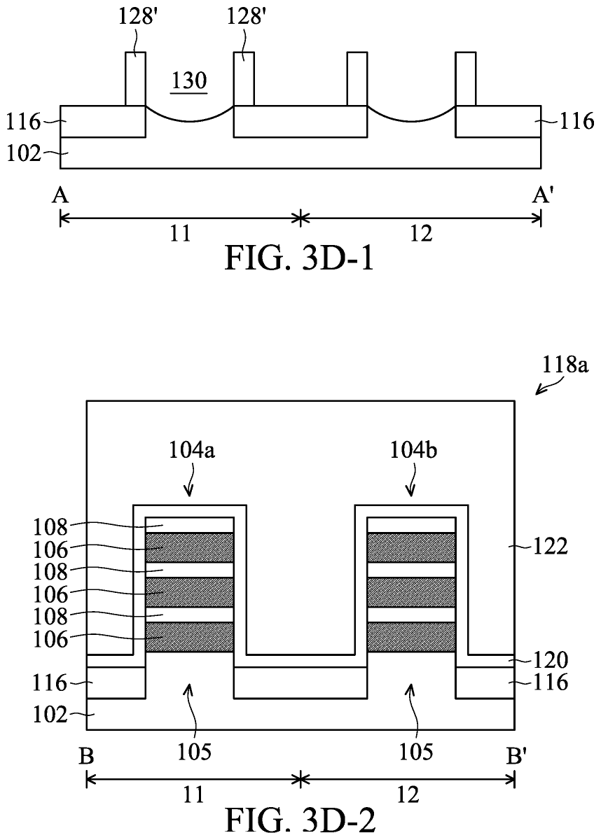

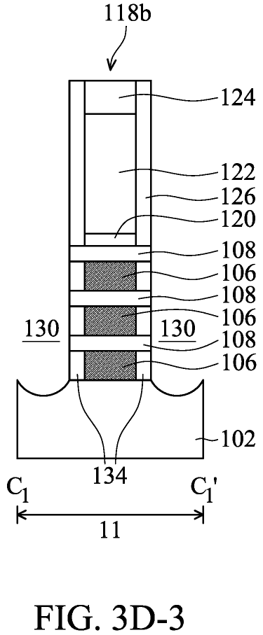

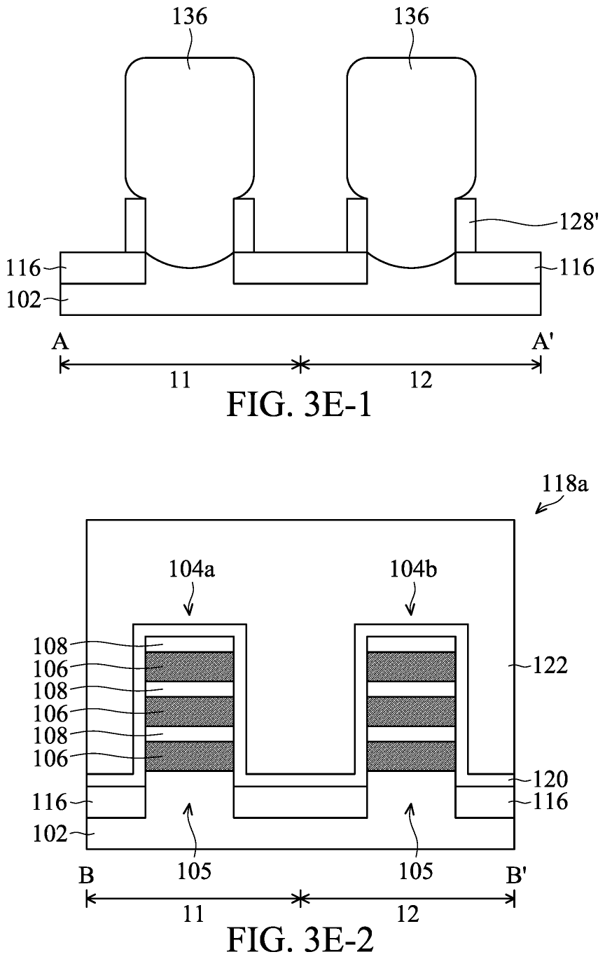

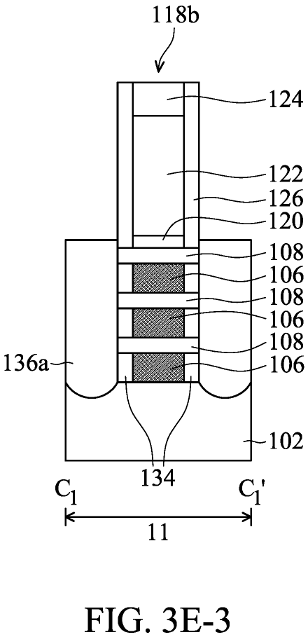

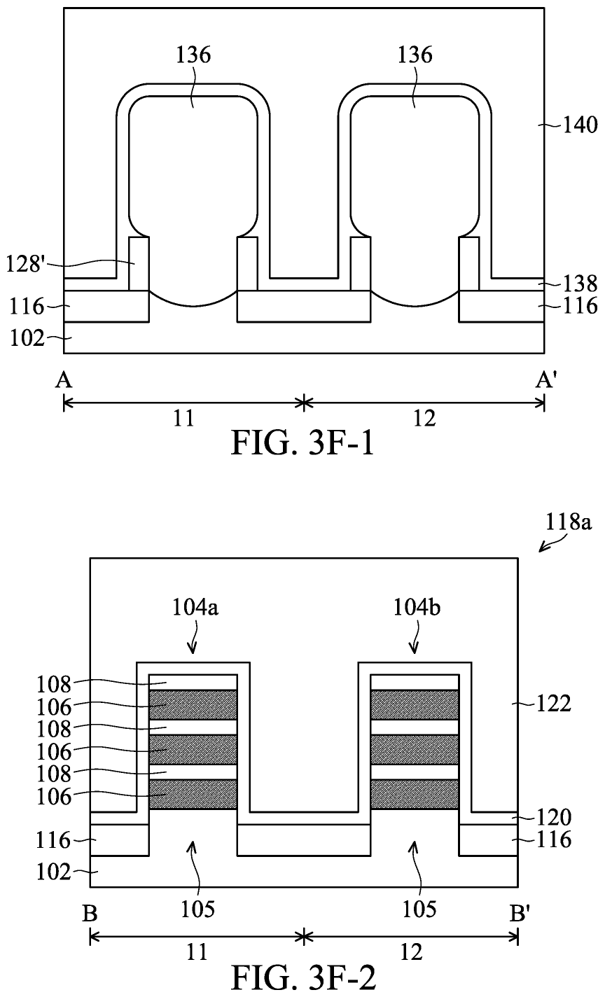

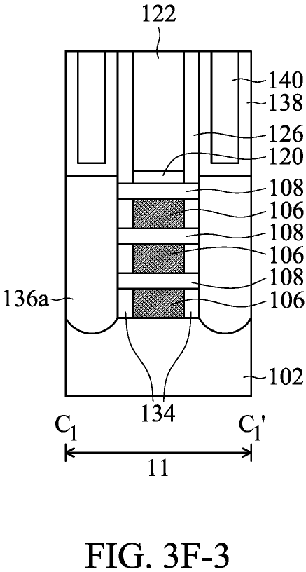

FIGS. 3A-1 to 3F-1 illustrate cross-sectional representations of various stages of manufacturing the semiconductor structure 100a shown along line A-A′ in FIG. 1E and in FIG. 2, in accordance with some embodiments. FIGS. 3A-2 to 3F-2 illustrate cross-sectional representations of various stages of manufacturing the semiconductor structure 100a shown along line B-B′ in FIG. 1E and in FIG. 2, in accordance with some embodiments. FIGS. 3A-3 to 3F-3 illustrate cross-sectional representations of various stages of manufacturing the semiconductor structure 100a shown along line C₁-C₁′ in FIG. 1E and in FIG. 2, in accordance with some embodiments.

More specifically, FIG. 3A-1 illustrates the cross-sectional representation shown along line A-A″ in FIG. 1E and FIG. 2. FIG. 3A-2 illustrates the cross-sectional representation shown along line B-B′ in FIG. 1E and FIG. 2 in accordance with some embodiments. FIG. 3A-3 illustrates the cross-sectional representation shown along line C₁-C₁′ in FIG. 1E and in FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by first dummy gate structure 118a, the second dummy gate structure 118b and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, the first fin structure 104a and the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2 and 3C-3, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100a to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3D-1, 3D-2 and 3D-3, inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments. In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

Afterwards, as shown in FIGS. 3E-1, 3E-2 and 3E-3, after the inner spacer layers 134 are formed, source/drain (S/D) structure 136 are formed in the S/D recesses 130, in accordance with some embodiments.

In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the source/drain (S/D) structures 136 are in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain (S/D) structure 136 is doped in one or more implantation processes after the epitaxial growth process

Afterwards, as shown in FIGS. 3F-1, 3F-2 and 3F-3, a contact etch stop layer (CESL) 138 is conformally formed to cover the S/D structures 136, the second S/D structure 136b and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the first dummy gate structure 118a and the second dummy gate structure 118b are exposed, as shown in FIG. 31-3 in accordance with some embodiments.

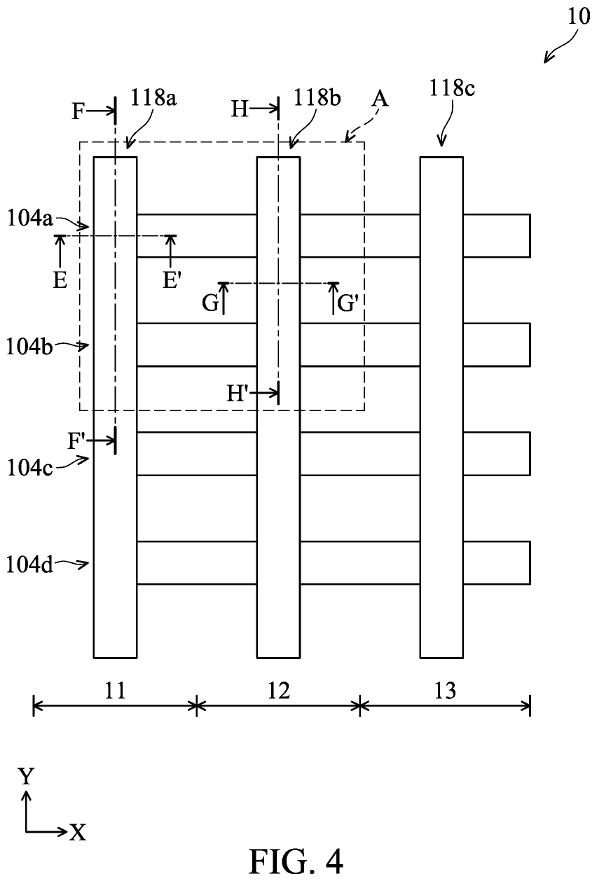

FIG. 4 shows a top-view representation of the semiconductor structure 100a, in accordance with some embodiments. FIG. 4 includes elements that are similar to, or the same as, elements of the semiconductor structure 100a of FIG. 2. The semiconductor structure 100a of FIG. 2 is the region A of the semiconductor structure of FIG. 4.

As shown in FIG. 4, the substrate 102 includes the first region 11, the second region 12 and the third region 13. The second fin structure 104b, the third fin structure 104c and the fourth fin structure 104d are parallel with the first fin structure 104a along the first direction (e.g. x-axis). The third dummy gate structure 118c is parallel with the second dummy gate structure 118b along the second direction (e.g. y-axis). The first dummy gate structure 118a is formed in the first region 11, the second dummy gate structure 118b is formed in the second region 12, and the third dummy gate structure 118c is formed in the third region 13.

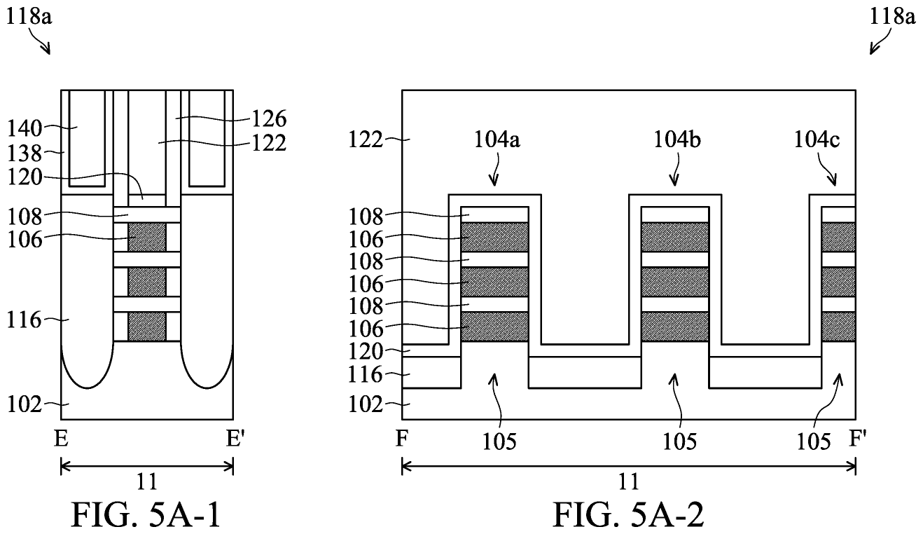

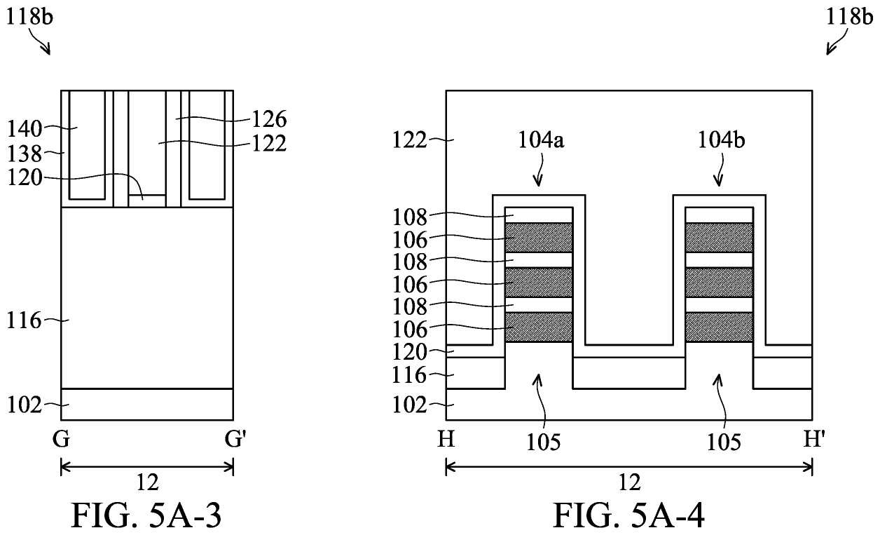

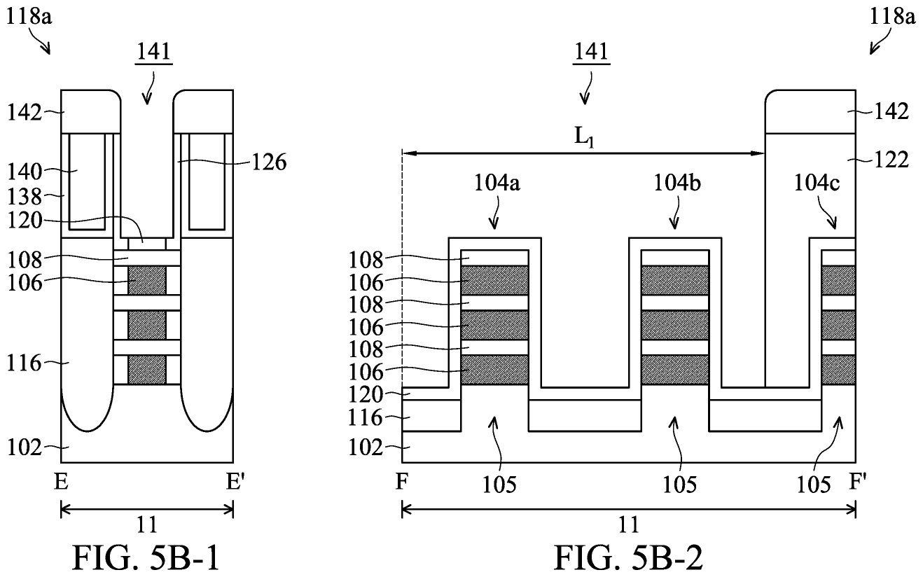

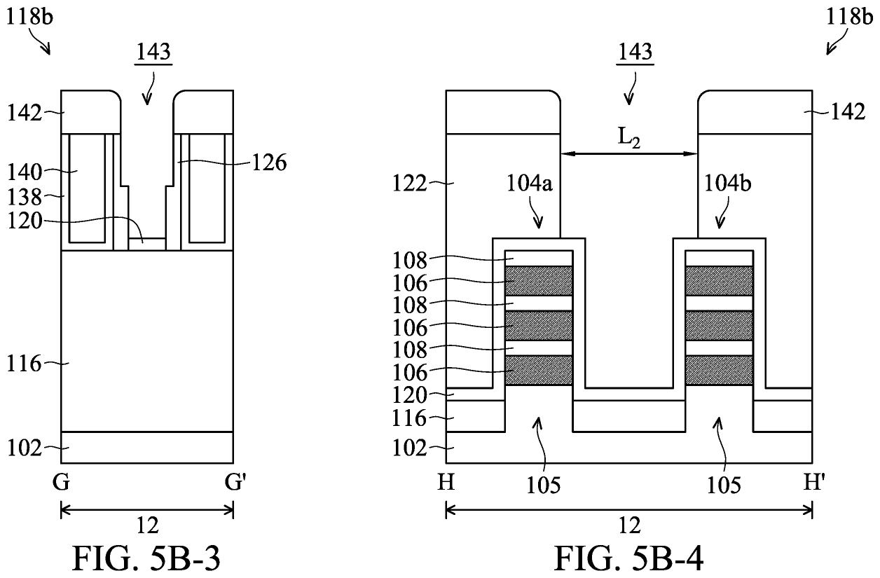

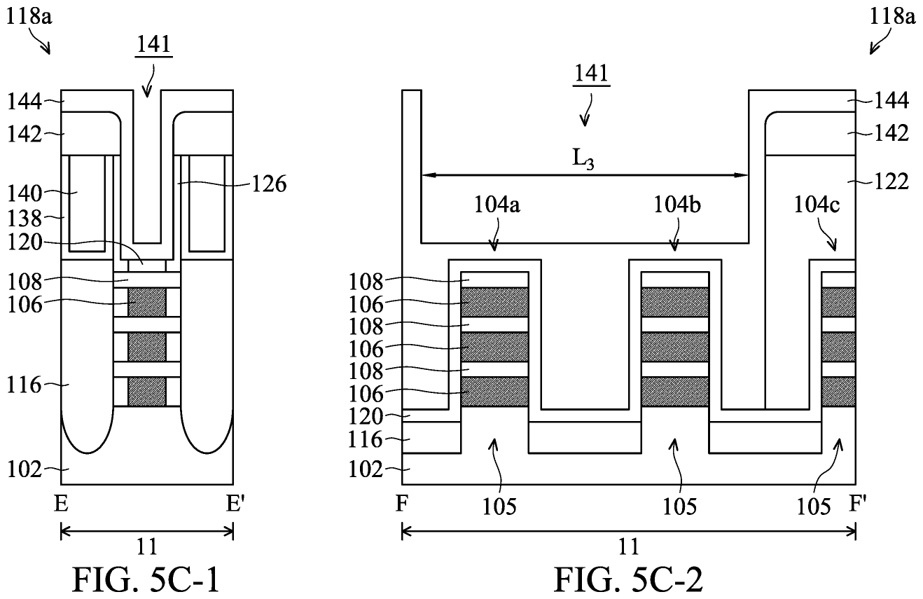

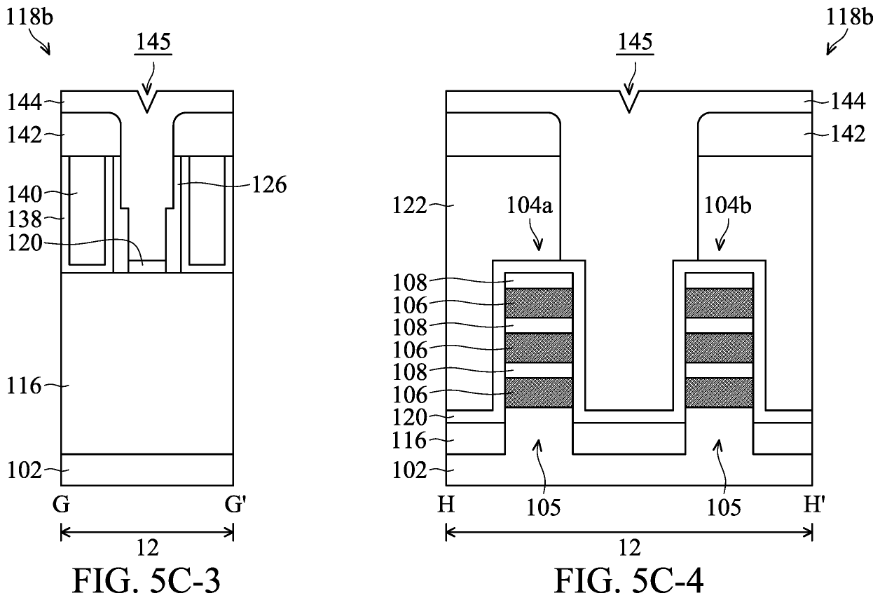

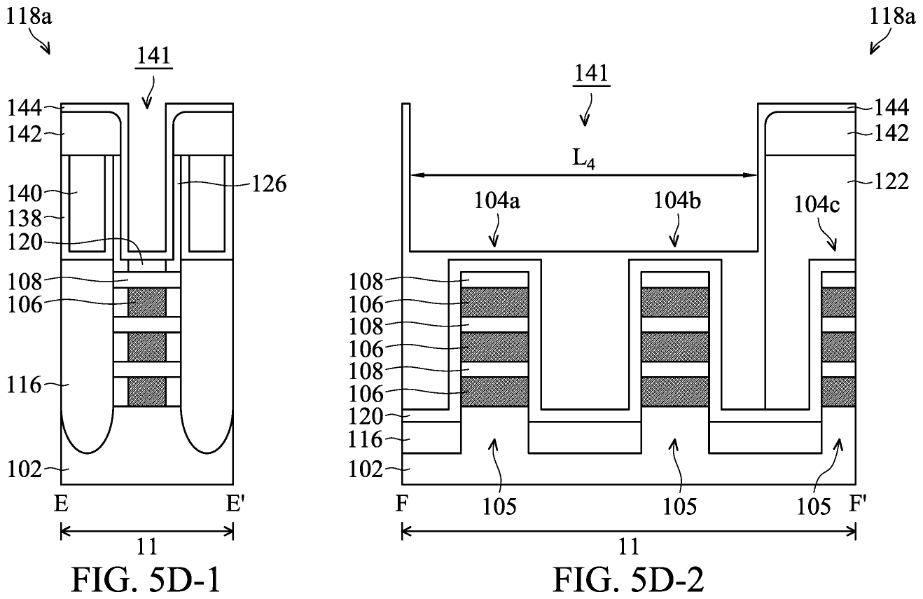

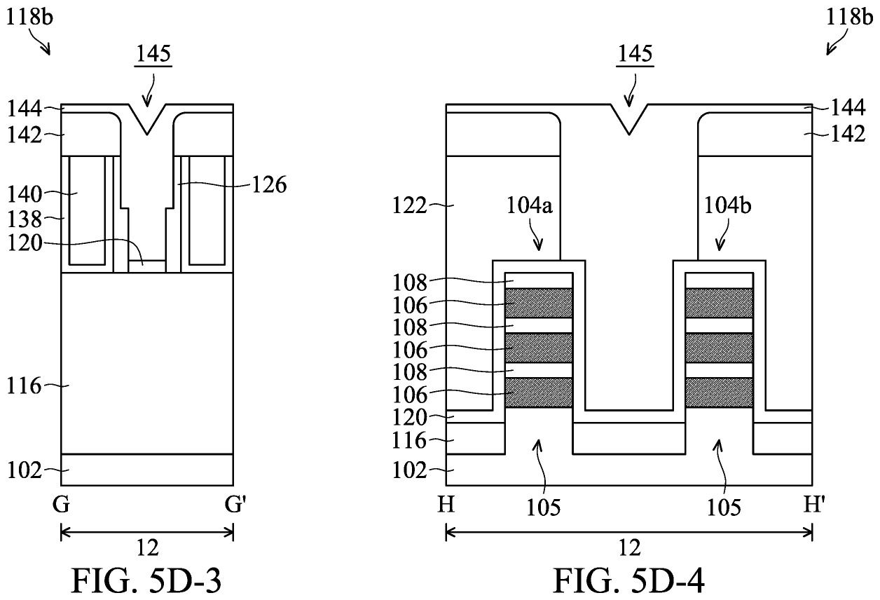

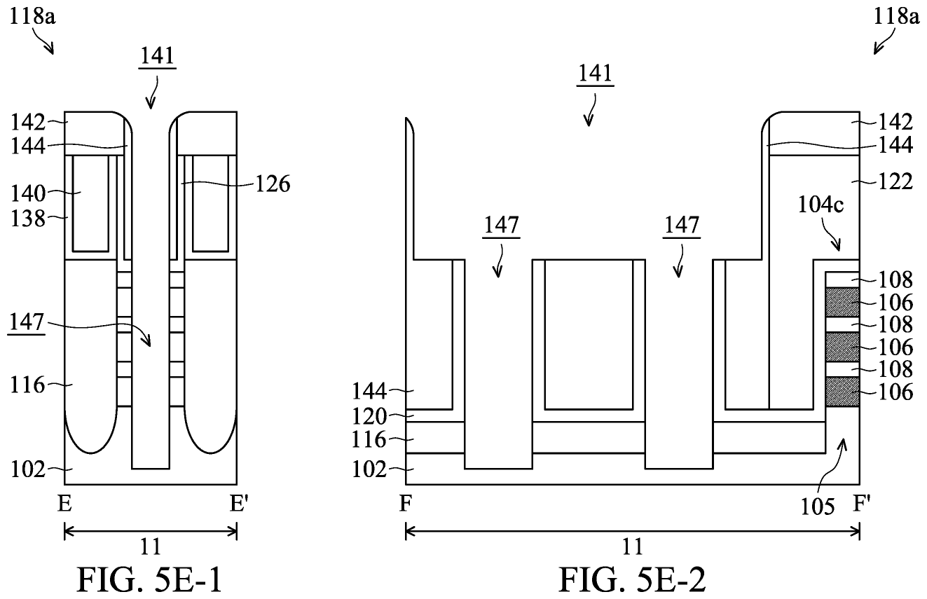

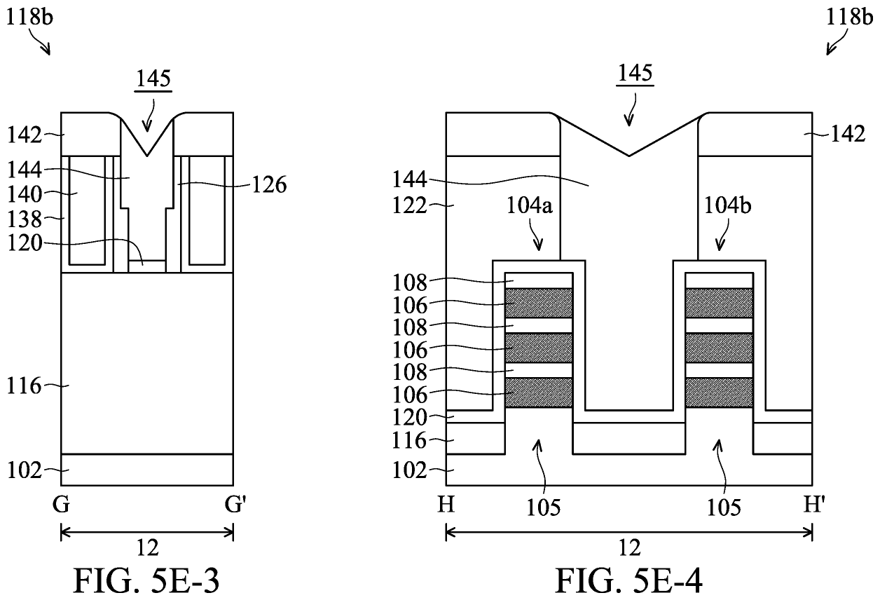

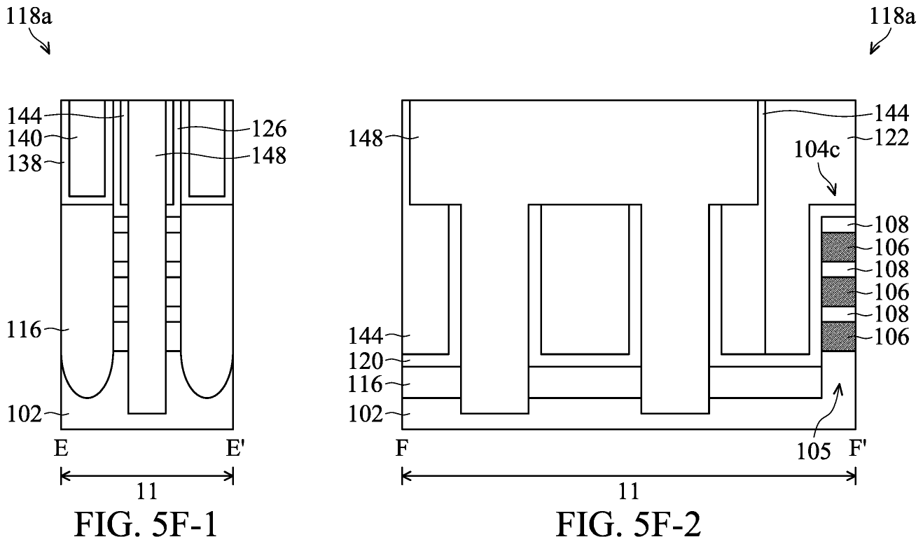

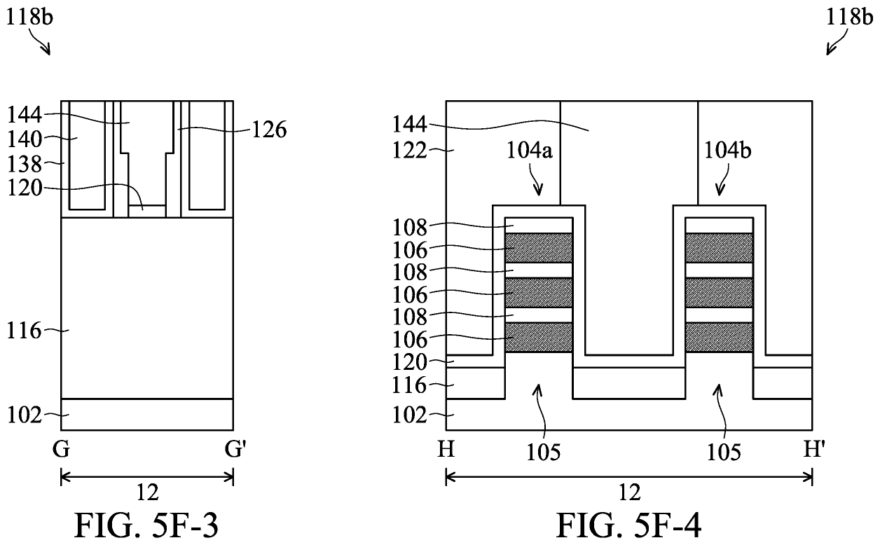

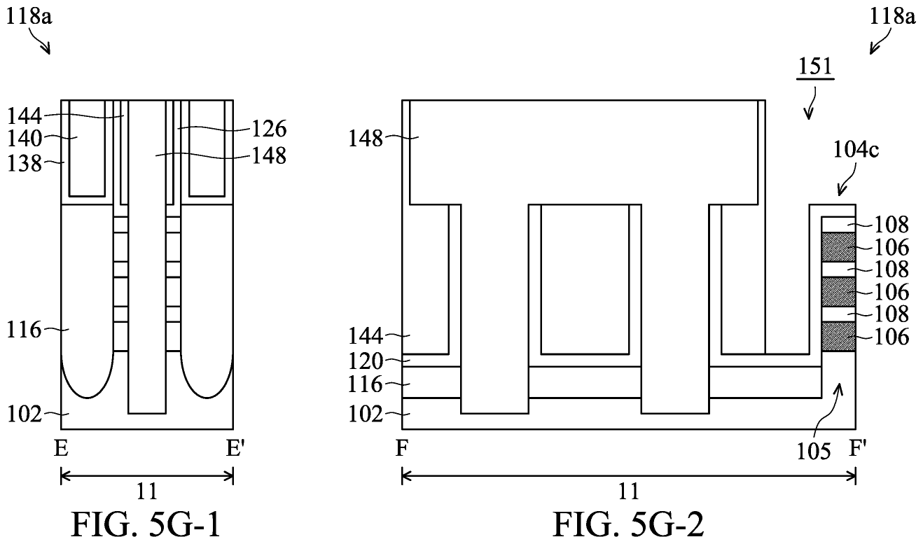

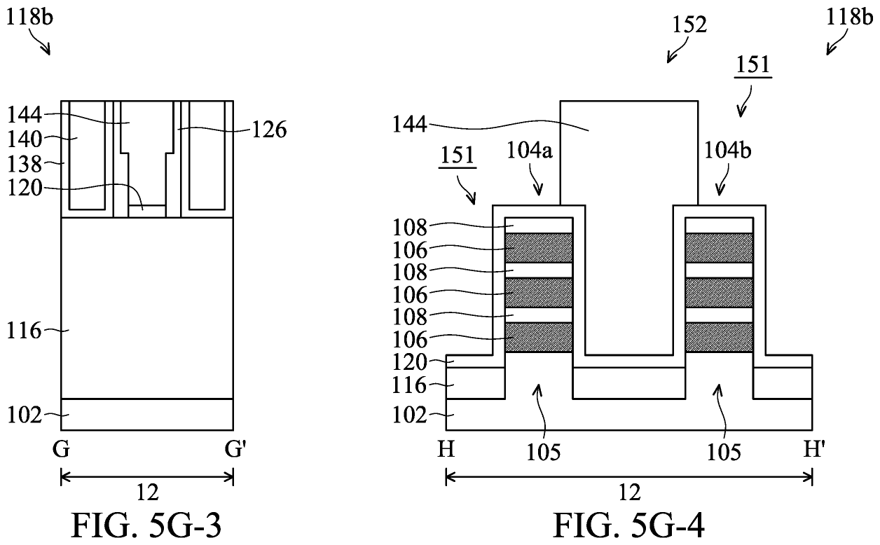

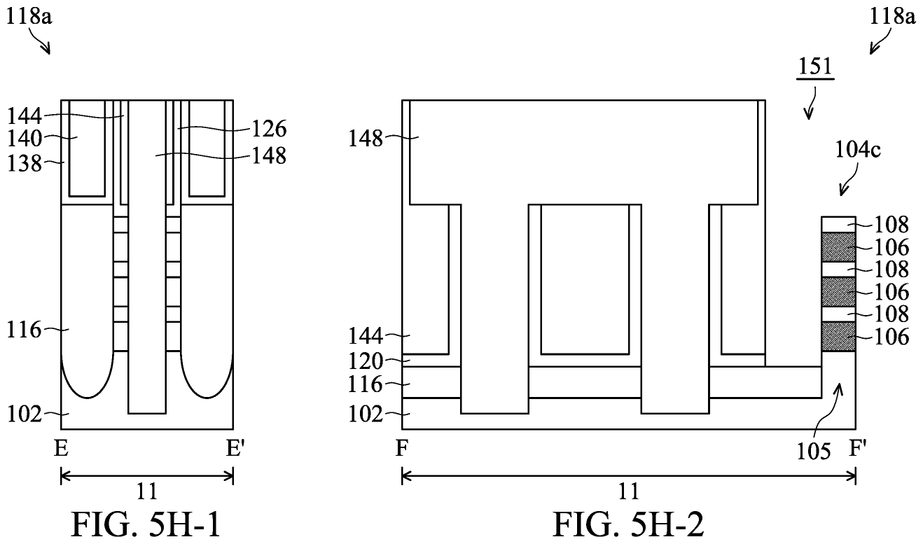

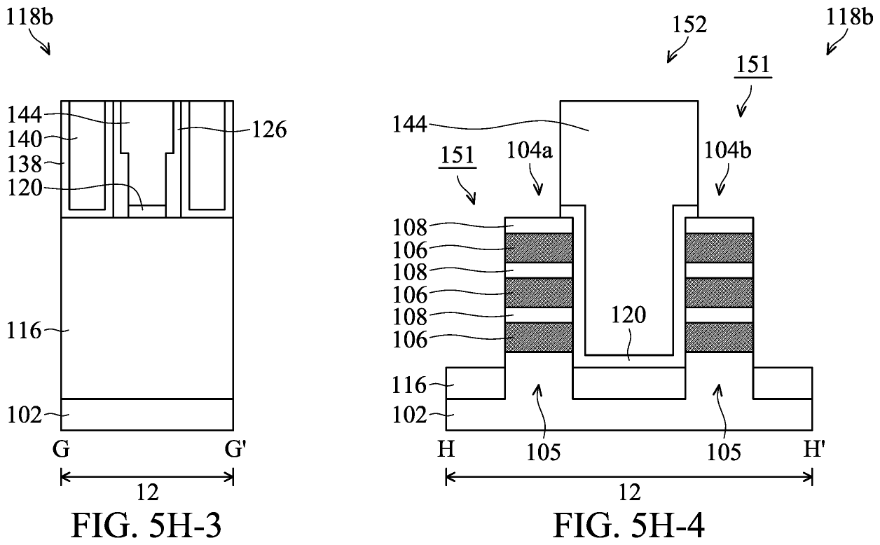

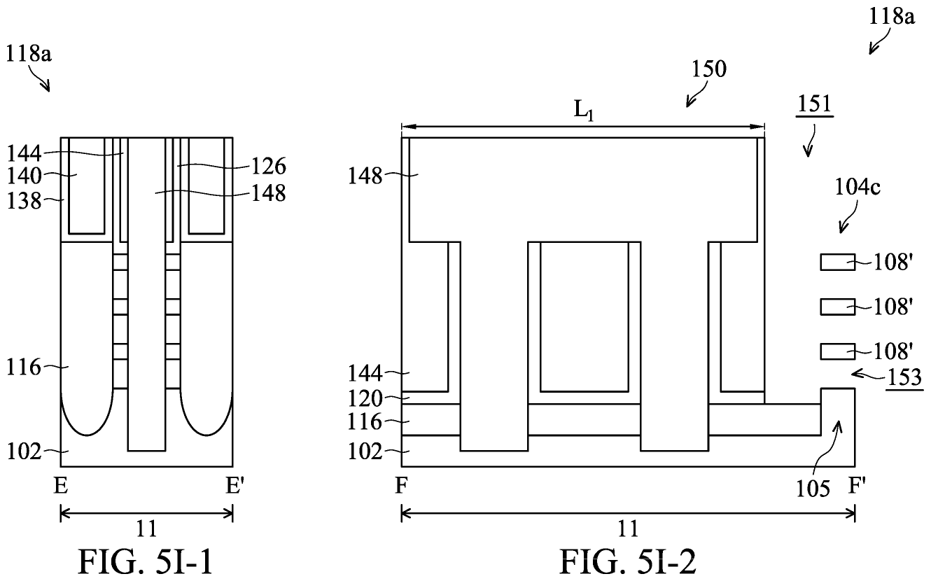

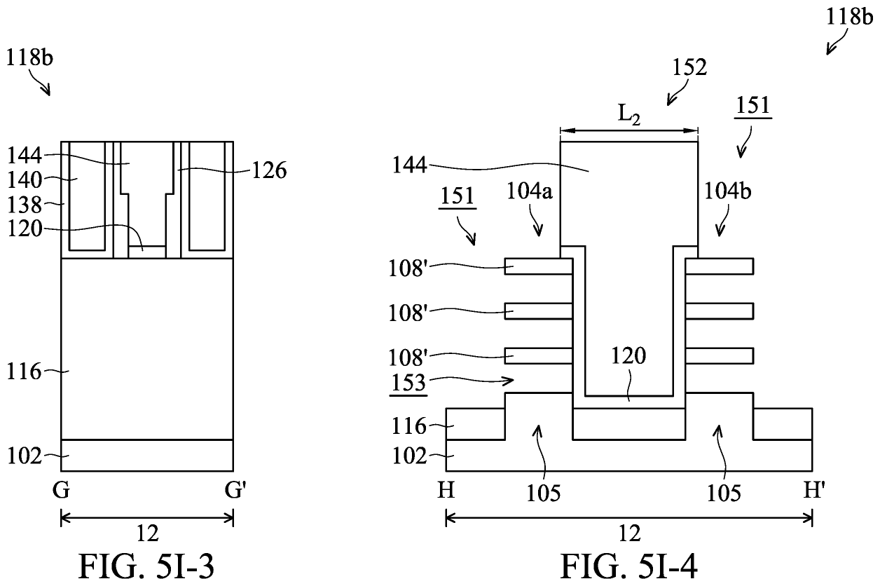

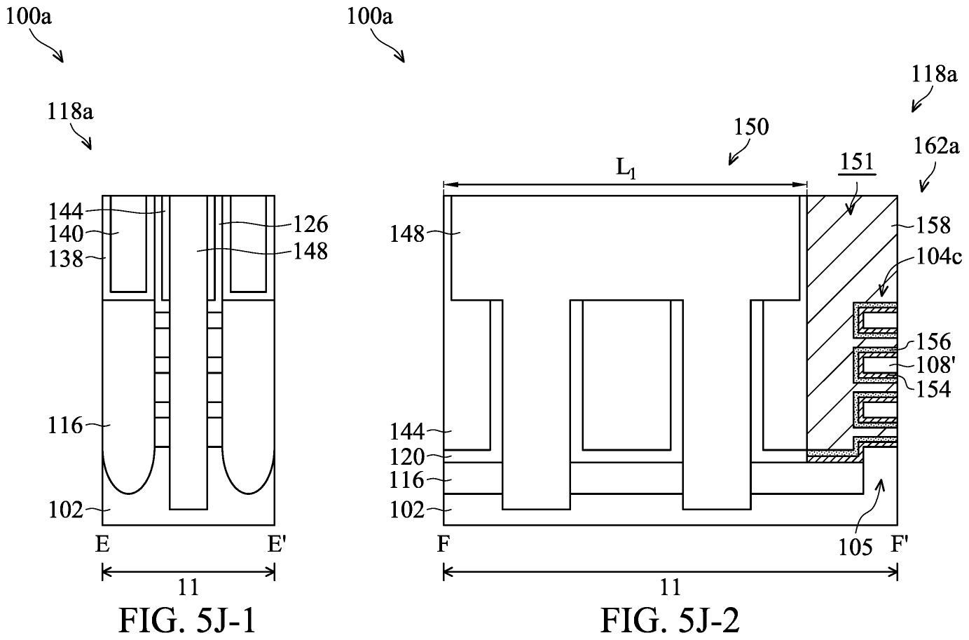

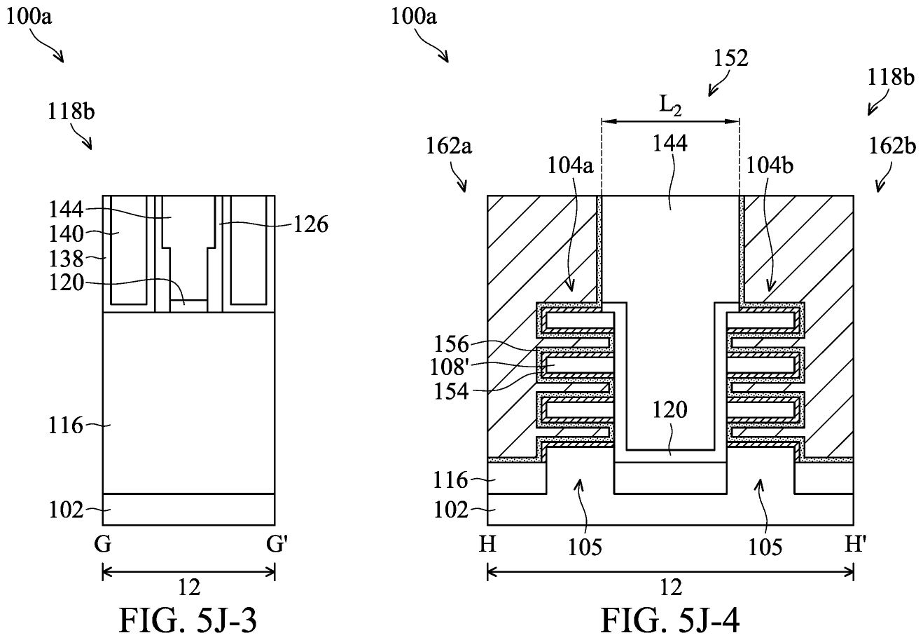

FIGS. 5A-1 to 5J-1 illustrate cross-sectional representations of various stages of manufacturing the semiconductor structure 100a shown along line E-E′ in FIG. 4, in accordance with some embodiments. FIGS. 5A-2 to 5J-2 illustrate cross-sectional representations of various stages of manufacturing the semiconductor structure 100a shown along line F-F′ in FIG. 4, in accordance with some embodiments. FIGS. 5A-3 to 5J-3 illustrate cross-sectional representations of various stages of manufacturing the semiconductor structure 100a shown along line G-G′ in FIG. 4, in accordance with some embodiments. FIGS. 5A-4 to 5J-4 illustrate cross-sectional representations of various stages of manufacturing the semiconductor structure 100a shown along line H-H′ in FIG. 4, in accordance with some embodiments.

After the contact etch stop layer 138 and the ILD layer 140 are formed, as shown in FIGS. 5A-1 and 5A-2, the first dummy gate structure 118a is formed over the first fin structure 104a, the second fin structure 104b, the third fin structure 104c and the fourth fin structure 104d in the first region 11. As shown in FIGS. 5A-3 and 5A-4, the second dummy gate structure 118b is formed over the first fin structure 104a, the second fin structure 104b, the third fin structure 104c and the fourth fin structure 104d in the second region 12.

Afterwards, as shown in FIG. 5B-1 and 5B-2, in the first region 11, a hard mask layer 142 is formed on the ILD layer 140 and the first dummy gate structure 118a, and the hard mask layer 142 is patterned, in accordance with some embodiments. Next, the hard mask layer 142 is patterned to form the patterned hard mask layer 142. Afterwards, a portion of the first dummy gate structure 118a is removed to form a trench 141 by using the patterned hard mask layer 142 as a mask, in accordance with some embodiments. More specifically, the dummy gate electrode layer 122 of the first dummy gate structure 118a is removed by the etching process.

The gate spacer layer 126 is exposed by the trench 141. In addition, the dummy gate dielectric layer 120 is exposed by the trench 141. The trench 141 has a first length L₁ along the second direction (e.g. y-axis). The first length L₁ is greater than the sum of the length of the first fin structure 104a and the length of the second fin structure 104b along the second direction (e.g. y-axis).

In some embodiments, the hard mask layer 142 is made of silicon nitride, silicon oxynitride, or another applicable material. In some embodiments, the hard mask layer 142 is formed by chemical vapor deposition (CVD), physical vapor deposition, (PVD), atomic layer deposition (ALD), or other applicable processes.

The portion of the dummy gate electrode layer 122 of the first dummy gate structure 118a is removed by an etching process. In some embodiments, the etching process is a dry etching process. In some embodiments, the etching gas used in the dry etching process includes using fluorine (F)-containing gas, chloride (Cl)-containing gas hydrogen bromide (HBr) or another applicable gas.

As shown in FIG. 5B-3 and 5B-4, in the second region 12, the hard mask layer 142 is formed on the ILD layer 140 and the second dummy gate structure 118b, and the hard mask layer 142 is patterned, in accordance with some embodiments. Next, a portion of the second dummy gate structure 118b is removed to form an opening 143, in accordance with some embodiments. The dummy gate dielectric layer 120 is exposed by the opening 143. The opening 143 has a second length L₂ along the second direction (e.g. y-axis). In some embodiments, the first length L₁ is greater than the second length L₂.

Next, as shown in FIG. 5C-1 and 5C-2, in the first region 11, a protection layer 144 is formed in the trench 141, in accordance with some embodiments. The protection layer 144 is used to protect the underlying layers from being damaged by the following steps.

Since the first length L₁ of trench 141 is greater than the second length L₂ of the opening 143, the opening 143 is completely filled with the protection layer 144, but the trench 141 is not completely filled with the protection layer 144. After forming the protection layer 144, the trench 141 has a third length L₃. The third length L₃ is smaller than the first length L₁.

As shown in FIG. 5C-3 and 5C-4, in the second region 12, the opening 143 is completely filled with the protection layer 144, in accordance with some embodiments. The top portion of the protection layer 144 has a recess 145. The bottom surface of the recess 145 is higher than the top surface of the hard mask layer 142.

In some embodiments, the protection layer 144 is made of silicon nitride (SiN), silicon carbide (SiC), silicon oxynitride (SiON), silicon carbon nitride (SiCN), silicon oxide carbonitride (SiOCN), and/or a combination thereof. In some embodiments, the protection layer 144 is formed by chemical vapor deposition (CVD), physical vapor deposition, (PVD), atomic layer deposition (ALD), or other applicable processes.

Afterwards, as shown in FIG. 5D-1 and 5D-2, in the first region 11, a sidewall portion of the protection layer 144 is removed to enlarge the third length L₃ of the trench 141, in accordance with some embodiments. As a result, the fourth length L₄ of the trench 141 is obtained, and the fourth length L₄ is greater than the third length L₃. The sidewall portion of the protection layer 144 is removed to enlarge opening of the trench 141. The enlarged opening of the trench 141 can make the removal of the first fin structure 104a and the second fin structure 104b easier in the following steps.

In some embodiments, the sidewall portion of the protection layer 144 is removed by a wet etching process. Since the opening 143 in the second region 12 (shown in FIG. 5C-4) is still filled with the protection layer 144, the protection layer 144 in the opening 143 is hardly removed by the wet etching process.

As shown in FIG. 5D-3 and 5D-4, in the second region 12, the recess 145 of the protection layer 144 is slightly enlarged, but the opening 143 is still filled with the protection layer 144, in accordance with some embodiments. In addition, the bottom surface of the recess 145 is still higher than the top surface of the hard mask layer 142.

Afterwards, as shown in FIG. 5E-1 and 5E-2, in the first region 11, a portion of the protection layer 144 is removed to expose the first fin structure 104a and the second fin structure 104b, and then the exposed first fin structure 104a and the exposed second fin structure 104b are removed to form a recess 147, in accordance with some embodiments. As a result, the recess 147 is below the trench 141, and the bottom surface of the recess 147 is lower than the bottom surface of the isolation structure 116, and the substrate 102 is exposed by the recess 147.

As shown in FIG. 5E-3 and 5E-4, in the second region 12, the recess 145 of the protection layer 144 is slightly enlarged, but the opening 143 is still filled with the protection layer 144, in accordance with some embodiments.

Afterwards, as shown in FIG. 5F-1 and 5F-2, in the first region 11, a filling layer 148 is formed in the recess 147 and the trench 141, in accordance with some embodiments. Next, the planarization process may be a CMP process or an etch-back process to remove excess filling material outside the trench 141. As a result, the filling layer 148 is surrounded by the protection layer 144 and the dummy gate dielectric layer 120. As a result, the filling layer 148 has a T-like shaped structure with two legs extended into the substrate 102.

The filling layer 148 may be a single layer or multiple layers. In some embodiments, the filling layer 148 is made of silicon oxide (SiOx), silicon nitride (SiN), silicon carbide (SiC), silicon oxynitride (SiON), silicon carbon nitride (SiCN), silicon oxide carbonitride (SiOCN), and/or a combination thereof. In some embodiments, the filling layer 148 includes the silicon oxide (SiOx) layer and the silicon nitride (SiN) layer. In some embodiments, the filling layer 148 is formed by a chemical vapor deposition (CVD), a physical vapor deposition, (PVD), an atomic layer deposition (ALD), or other applicable processes.

As shown in FIG. 5F-3 and 5F-4, in the second region 12, the filling layer 148 is formed in the recess 145 of the protection layer 144, in accordance with some embodiments.

Next, as shown in FIG. 5G-1 and 5G-2, in the first region 11, the dummy gate electrode layer 122 is removed to form a trench 151, but the protection layer 144 and the filling layer 148 are not removed, in accordance with some embodiments. Therefore, a dielectric strip structure 150 is obtained, and the dielectric strip structure 150 includes the protection layer 144 and the filling layer 148 surrounded by the protection layer 144. The dielectric strip structure 150 extends along the second direction (e.g. y-axis).

The dummy gate electrode layer 122 is removed by one or more etching processes. For example, when the dummy gate electrode layer 122 is polysilicon, a wet etchant such as a tetramethylammonium hydroxide (TMAH) solution may be used to selectively remove the dummy gate electrode layer 122.

As shown in FIG. 5G-3 and 5G-4, in the second region 12, the dummy gate electrode layer 122 is removed to form the trench 151, and the protection layer 144 is not removed, in accordance with some embodiments. Therefore, a dielectric wall structure 152 including the protection layer 144 is obtained. The dielectric wall structure 152 has a top portion and a bottom portion. The top portion is directly over the first fin structure 104a and the second fin structure 104b, and the bottom portion is surrounded by the dummy gate dielectric layer 120.

It should be noted that the protection layer 144 has a high etching selectivity

with respect to the dummy gate electrode layer 122, and therefore the protection layer 144 is not removed while the dummy gate electrode layer 122 is removed.

Next, as shown in FIG. 5H-1 and 5H-2, in the first region 11, a portion of the dummy gate dielectric layer 120 is removed which is not covered by the dielectric strip structure 150, in accordance with some embodiments.

The portion of the dummy gate dielectric layer 120 is removed by one or more etching processes. In some embodiments, the dummy gate dielectric layer 120 is removed by using a plasma dry etching, a dry chemical etching, and/or a wet etching.

As shown in FIG. 5H-3 and 5H-4, in the second region 12, a portion of the dummy gate dielectric layer 120 is removed which is not covered by the dielectric wall structure 152, in accordance with some embodiments.

Next, as shown in FIG. 51-1, 51-2, 51-3 and 51-4, the first semiconductor material layers 106 are removed to form nanostructures 108′ (or channel layers 108′) with the second semiconductor material layers 108, in accordance with some embodiments. As a result, gaps 153 are formed adjacent to the nanostructures 108′ (or channel layers 108′).

Afterwards, as shown in FIG. 5J-1, 5J-2, 5J-3 and 5J-4, after the nanostructures 108′ are formed, the interfacial layer 154, the gate dielectric layer 156, and the gate electrode layer 158 are formed in the trench 151 and the gaps 153, in accordance with some embodiments.

After the interfacial layers 154, the gate dielectric layers 156, and the gate electrode material are formed, a planarization process such as CMP or an etch-back process may be performed. After the planarization process, the gate electrode layer 158 is divided into two portions by the dielectric strip structure 150 and dielectric wall structure 148 to form a first gate structure 162a and a second gate structure 162b.

After the nanostructures 108′ are formed, the first gate structure 162a and the second gate structure 162b are formed wrapped around the nanostructures 108′. The first gate structure 162a and the second gate structure 162b wrap around the nanostructures 108′ to form gate-all-around transistor structures, in accordance with some embodiments. In some embodiments, the first gate structure 162a includes the interfacial layer 154, the gate dielectric layer 156, and the gate electrode layer 158. In some embodiments, the second gate structure 162b includes the interfacial layer 154, a gate dielectric layer 156, and the gate electrode layer 158.

In some embodiments, the interfacial layers 154 are oxide layers formed around the nanostructures 108′ and on the top of the base fin structure 105. In some embodiments, the interfacial layers 154 are formed by performing a thermal process.

In some embodiments, the gate dielectric layers 156 are formed over the interfacial layers 154, so that the nanostructures 108′ are surrounded (e.g. wrapped) by the gate dielectric layers 156. In addition, the gate dielectric layers 156 also cover the sidewalls of the gate spacer layers 126 and the inner spacer layers 134 in accordance with some embodiments. In some embodiments, the gate dielectric layers 156 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 156 are formed using chemical vapor deposition (CVD), atomic layer deposition (ALD), another applicable method, or a combination thereof.

In some embodiments, the first gate structure 162a and the second gate structure 162b are formed on the gate dielectric layer 156. In some embodiments, the first gate structure 162a and the second gate structure 162b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

In some embodiments, the first gate structure 162a and the second gate structure 162b are formed using chemical vapor deposition (CVD), atomic layer deposition (ALD), electroplating, another applicable method, or a combination thereof. Other conductive layers, such as work function metal layers, may also be formed in the first gate structure 162a and the second gate structure 162b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

As shown in FIG. 5J-1, the dielectric strip structure 150 is between two adjacent S/D structures 136. The bottom surface of the dielectric strip structure 150 is lower than the bottom surface of the S/D structure 136. In other words, the bottom surface of the S/D structure 136 is higher than the bottom surface of the dielectric strip structure 150. In some embodiments, the dielectric strip structure 150 is in direct contact with the inner spacer layers 134 and the gate spacer layer 126.

As shown in FIG. 5J-2, the dielectric strip structure 150 is formed adjacent to the nanostructures 108′ of the first gate structure 162a, in accordance with some embodiments. The dielectric strip structure 150 includes the protection layer 144 and the filling layer 148. In some embodiments, the protection layer 144 and the filling layer 148 are made of different materials, and therefore an interface between the protection layer 144 and the filling layer 148.

The dielectric strip structure 150 has a protruding portion which is lower than the bottom surface of the bottommost nanostructure 108′. In addition, the protruding portion of the dielectric strip structure 150 is lower than the bottom surface of the isolation structure 116. In other words, the bottom surface of the isolation structure 116 is higher than the bottom surface of the dielectric strip structure 150. The protruding portion of the dielectric strip structure 150 is in direct contact with the isolation structure 116 and the substrate 102.

As shown in FIG. 5J-4, the dielectric wall structure 152 is between the first gate structure 162a and the second gate structure 162b. The dielectric wall structure 152 has a first sidewall surface and a second sidewall surface. The first sidewall surface is in direct contact with the first gate structure 162a, and the second sidewall surface is in direct contact with the second gate structure 162b. The dielectric wall structure 152 has a top portion which is directly over the nanostructures 108′.

The gate dielectric layer 156 is formed on the sidewall surface of the dielectric wall structure 152. More specifically, the gate dielectric layer 156 is in direct contact with the dummy gate dielectric layer 120 and the dielectric wall structure 152.

The dielectric wall structure 152 and the dummy gate dielectric layer 120 are between the nanostructures 108′ of the first gate structure 162a and the nanostructures 108′ of the second gate structure 162b. The dummy gate dielectric layer 122 is made of dielectric material, and the dielectric wall structure 152 is also made of dielectric material. Therefore, the first gate structure 162a is isolated from the second gate structure 162b by the dielectric wall structure 152 and the dummy gate dielectric layer 122. The dielectric wall structure 152 is isolated from one of the nanostructures 108′ by the dummy gate dielectric layer 120. The dummy gate dielectric layer 120 has a U-shaped structure to surround and in direct contact with the dielectric wall structure 152.

As shown in FIGS. 5J-2 and 5J-4, the bottom surface of the dielectric wall structure 152 is higher than the bottom surface of the dielectric strip structure 150. The dielectric wall structure 152 has a T-shaped structure, and is surrounded by the U-shaped dummy gate dielectric layer 120. The dielectric strip structure 150 has a T-like shaped structure with two extending legs downwardly extended into the isolation structure 116.

Since one side of the nanostructure 108′ is in direct contact with the dummy gate dielectric layer 122, rather than the gate electrode layer 158, the effective width (W_{eff}) of nanostructure 108′ (or channel layer 108′) is reduced. When the effective width (W_{eff}) of nanostructure 108′ (or channel layer 108′) is reduced, the current of the semiconductor layer 100a can be reduced for power efficiency. In other words, the dielectric wall structure 152 extends along the second direction, and is close to the nanostructure 108′, the power consumption can be reduced. Therefore, the semiconductor layer 100a can applied in power efficiency device, and the performance of the semiconductor layer 100a is improved.

Furthermore, the trench 141 (shown in FIG. 5B-2) for forming the dielectric strip structure 150 and the opening 143 (shown in FIG. 5B-4) for forming the dielectric wall structure 152 are defined by the same mask. Since the first length L₁ of the trench 141 is greater than the second length L₂ of the opening 143, the opening 143 (shown in FIG. 5C-4) is completely filled with the protection layer 144, but the trench 141 is not completely filled with the protection layer 144 (shown in FIG. 5C-2). The trench 141 is further filled with the filling layer 148 to form the dielectric strip structure 150. The dielectric wall structure 152 can be formed by filling the opening 143 with the protection layer 144, and the dielectric strip structure 150 can be formed by filling the trench 141 with the protection layer 144 and the filling layer 148. The dielectric wall structure 152 and the dielectric strip structure 150 can be formed by the same mask without using extra mask. Therefore, the fabrication time and cost can be reduced.

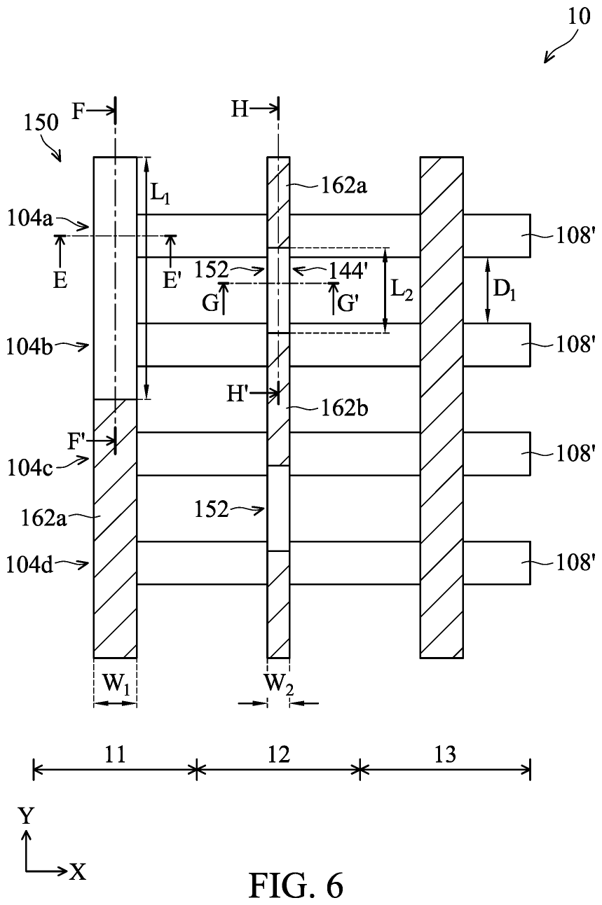

FIG. 6 shows a top-view representation of the semiconductor structure 100a after forming the first gate structure 160a and the second gate structure 160b, in accordance with some embodiments.

As shown in FIG. 6, the dielectric strip structure 150 is parallel with the dielectric wall structure 152. The dielectric strip structure 150 is across the first fin structures 104a and the second fin structure 104b, and the dielectric wall structure 152 is between the fin structures 104a and the second fin structure 104b.

The dielectric strip structure 150 has a first length L₁ along the second direction (e.g. y-axis), and the dielectric wall structure 152 has a second length L₂ along the second direction (e.g. y-axis). In some embodiments, the first length L₁ is greater than the second length L₂. The second length L₂ of the dielectric wall structure 152 is greater than the distance D₁ between two adjacent nanostructures 108′ along the second direction (e.g. y-axis).

The dielectric strip structure 150 has a first width W₁ along the first direction (e.g. x-axis), and the dielectric wall structure 152 has a second width W₂ along the first direction (e.g. x-axis). In some embodiments, the first width W₁ is greater than the second width W₂.

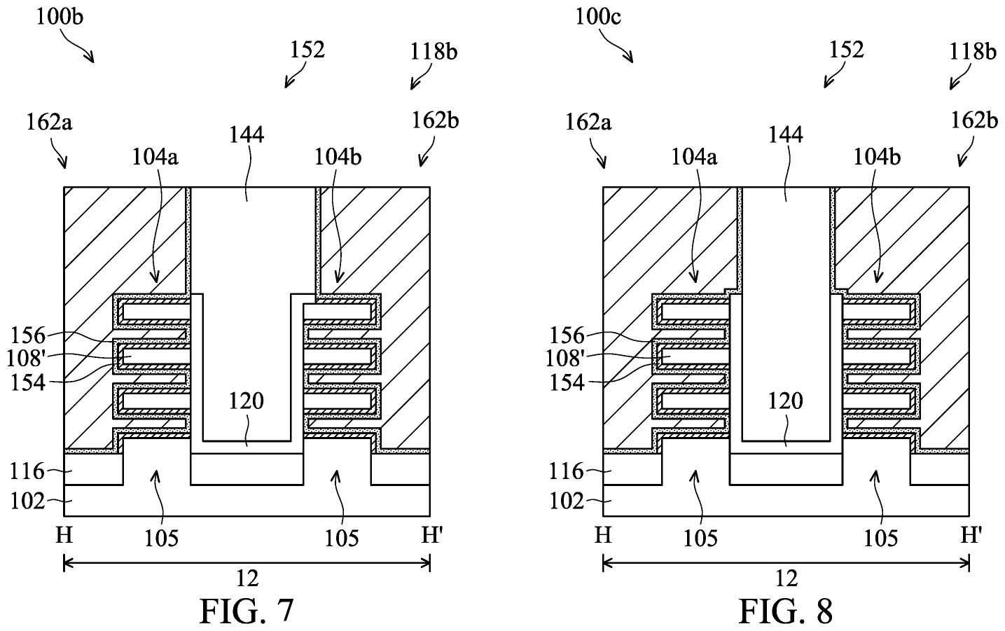

FIG. 7 illustrates a cross-sectional representation of a semiconductor structure 100b, in accordance with some embodiments. The semiconductor structure 100b of FIG. 7 includes elements that are similar to, or the same as, elements of the semiconductor structure 100a of FIG. 5J-4.

FIG. 7 is are similar to, or the same as, FIG. 5J-4, the difference between FIG. 7 and FIG. 5J-4 is that the dielectric wall structure 152 is not symmetric to the central line of the dielectric wall structure 152. More specifically, the right portion of the dielectric wall structure 152 is directly formed on the nanostructures 108′, but the left portion of the dielectric wall structure 152 is not directly formed on the nanostructures 108′. In addition, the right portion of the dielectric wall structure 152 is in direct contact with the right topmost surface of the dummy gate dielectric layer 120.

The right sidewall surface of the dielectric wall structure 152 is substantially aligned with the outer sidewall surface of the dummy gate dielectric layer 120. The left sidewall surface of the dielectric wall structure 152 is aligned with the inner sidewall surface of the dummy gate dielectric layer 120.

FIG. 8 illustrates a cross-sectional representation of a semiconductor structure 100c, in accordance with some embodiments. The semiconductor structure 100c of FIG. 8 includes elements that are similar to, or the same as, elements of the semiconductor structure 100a of FIG. 5J-4.

FIG. 8 is are similar to, or the same as, FIG. 5J-4, the difference between FIG. 8 and FIG. 5J-4 is that the dielectric wall structure 152 has a rectangular shape, and is surrounded by the U-shaped dummy gate dielectric layer 120. The dielectric wall structure 152 is not directly formed on the nanostructures 108′.

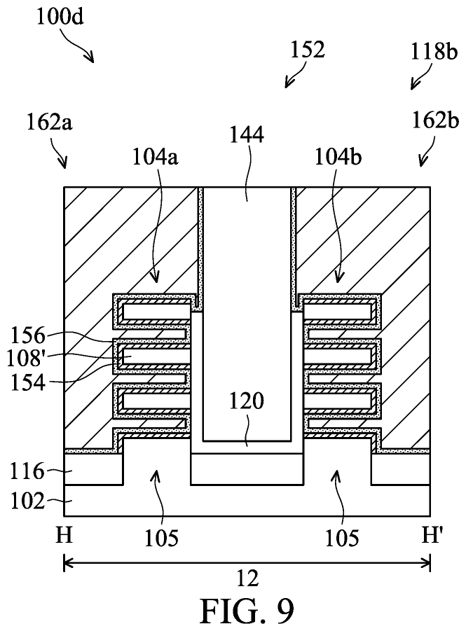

FIG. 9 illustrates a cross-sectional representation of a semiconductor structure 100d, in accordance with some embodiments. The semiconductor structure 100d of FIG. 9 includes elements that are similar to, or the same as, elements of the semiconductor structure 100c of FIG. 8.

FIG. 9 is are similar to, or the same as, FIG. 8, the difference between FIG. 9 and FIG. 8 is that the topmost surface of the dummy gate dielectric layer 122 is lower than the topmost surface of the nanostructures 108′.

It should be noted that a portion of the gate electrode layer 148 is in a space between the dielectric wall structure 152 and the nanostructure 108′. The portion of the gate electrode layer 148 is in direct contact with the dummy gate dielectric layer 120.

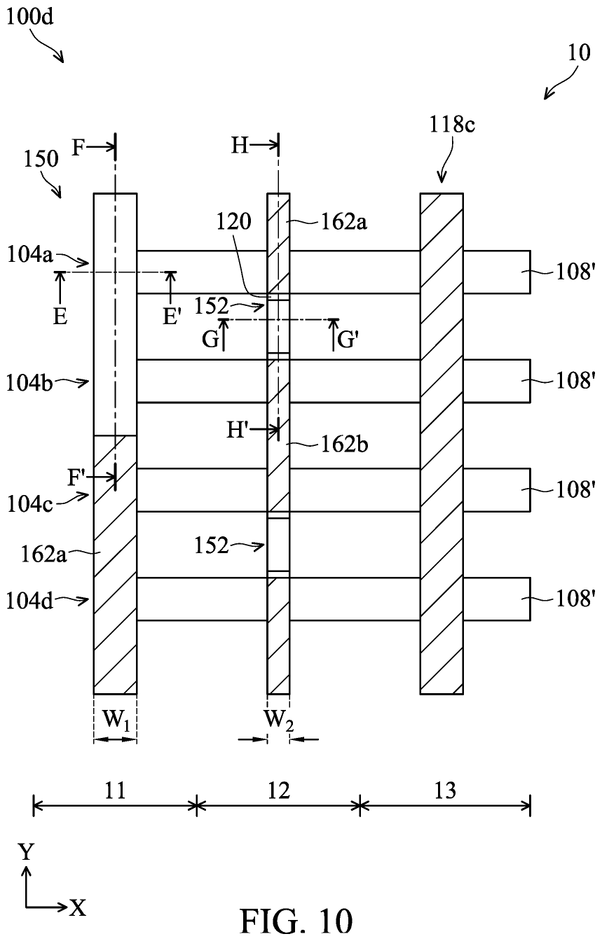

FIG. 10 shows a top-view representation of the semiconductor structures 100c or 100d after forming the first gate structure 160a and the second gate structure 160b, in accordance with some embodiments. FIG. 8 illustrates a cross-sectional representation of the semiconductor structure 100c shown along line H-H′ in FIG. 10, in accordance with some embodiments. FIG. 9 illustrates a cross-sectional representation of the semiconductor structure 100d shown along line H-H′ in FIG. 10, in accordance with some embodiments.

As shown in FIG. 10, the dielectric wall structure 152 is formed between the first gate structure 162a and the second gate structure 162b. The dielectric wall structure 152 is formed along the second direction (e.g. y-axis). The dummy gate dielectric layer 120 is between the nanostructures 108′ and the dielectric wall structure 152.

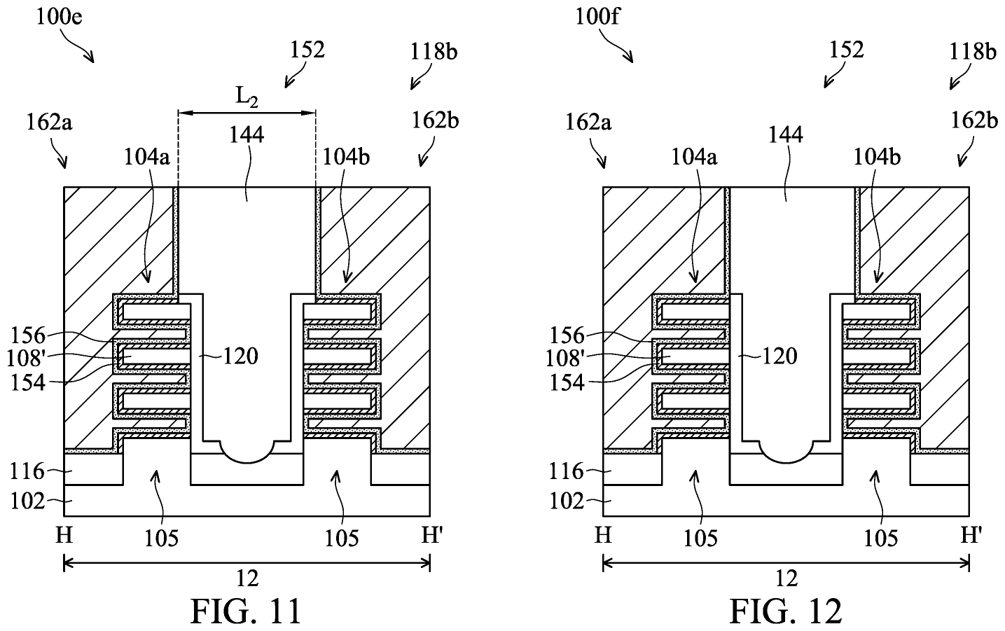

FIG. 11 illustrates a cross-sectional representation of a semiconductor structure 100e, in accordance with some embodiments. The semiconductor structure 100e of FIG. 11 includes elements that are similar to, or the same as, elements of the semiconductor structure 100a of FIG. 5J-4.

FIG. 11 is are similar to, or the same as, FIG. 5J-4, the difference between FIG. 11 and FIG. 5J-4 is that the dielectric wall structure 152 includes a protruding portion, and the protruding portion of the dielectric wall structure 152 is lower than the top surface of the isolation structure 116. Furthermore, the protruding portion of the dielectric wall structure 152 is lower than the bottommost surface of the nanostructures 108′.

When the portion of the dummy gate electrode layer 122 is removed to form the opening 143, the exposed dummy gate dielectric layer 120 and the isolation structure 116 may be removed. Therefore, a recess (not shown) is formed, and the dielectric material is filled into the recess to from the dielectric wall structure 152 with the protruding portion.

FIG. 12 illustrates a cross-sectional representation of a semiconductor structure 100f, in accordance with some embodiments. The semiconductor structure 100f of FIG. 12 includes elements that are similar to, or the same as, elements of the semiconductor structure 100b of FIG. 7.

FIG. 12 is are similar to, or the same as, FIG. 7, the difference between FIG. 12 and FIG. 7 is that the dielectric wall structure 152 includes a protruding portion, and the protruding portion of the dielectric wall structure 152 is lower than the top surface of the isolation structure 116. Furthermore, the protruding portion of the dielectric wall structure 152 is lower than the bottommost surface of the nanostructures 108′.

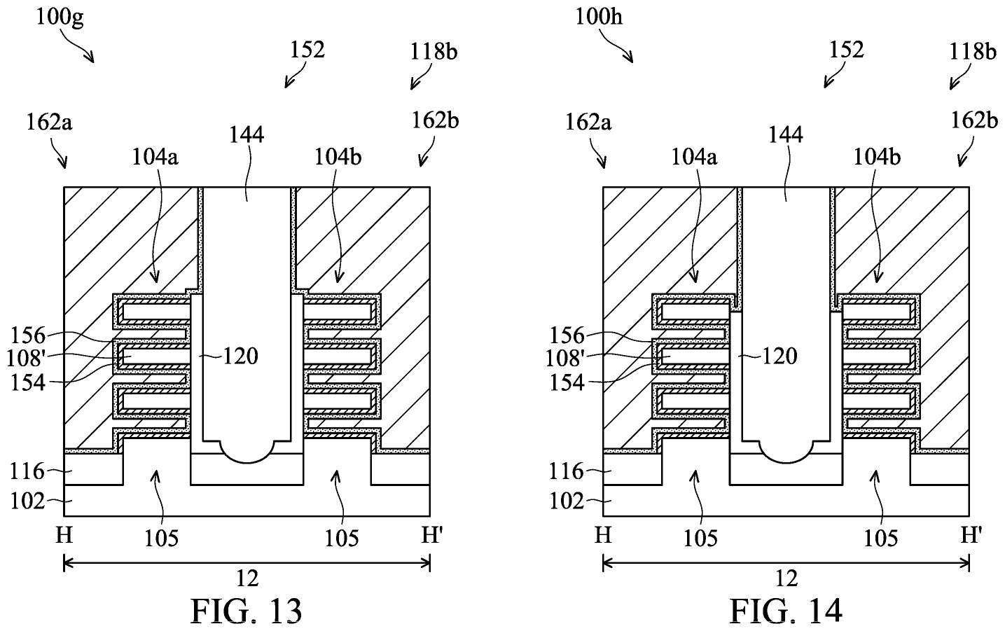

FIG. 13 illustrates a cross-sectional representation of a semiconductor structure 100g, in accordance with some embodiments. The semiconductor structure 100g of FIG. 13 includes elements that are similar to, or the same as, elements of the semiconductor structure 100c of FIG. 8.

FIG. 13 is are similar to, or the same as, FIG. 8, the difference between FIG. 13 and FIG. 8 is that the dielectric wall structure 152 includes a protruding portion, and the protruding portion of the dielectric wall structure 152 is lower than the top surface of the isolation structure 116. Furthermore, the protruding portion of the dielectric wall structure 152 is lower than the bottommost surface of the nanostructures 108′.

FIG. 14 illustrates a cross-sectional representation of a semiconductor structure 100h, in accordance with some embodiments. The semiconductor structure 100h of FIG. 14 includes elements that are similar to, or the same as, elements of the semiconductor structure 100d of FIG. 9.

FIG. 14 is are similar to, or the same as, FIG. 9, the difference between FIG. 14 and FIG. 9 is that the dielectric wall structure 152 includes a protruding portion, and the protruding portion of the dielectric wall structure 152 is lower than the top surface of the isolation structure 116. Furthermore, the protruding portion of the dielectric wall structure 152 is lower than the bottommost surface of the nanostructures 108′.

Since one side of the nanostructure 108′ is in direct contact with the dummy gate dielectric layer 122, rather than the gate electrode layer 158, the effective width (W_{eff}) of nanostructure 108′ (or channel layer 108′) is reduced. When the effective width (W_{eff}) of nanostructure 108′ (or channel layer 108′) is reduced, the current of the semiconductor layer 100a can be reduced for power efficiency. In other words, the dielectric wall structure 152 extends along the second direction, and is close to the nanostructure 108′, the power consumption can be reduced. Therefore, the semiconductor layer 100a can applied in power efficiency device, and the performance of the semiconductor layer 100a is improved.

It should be noted that same elements in FIGS. 1A to 14 may be designated by the same numerals and may include similar or the same materials and may be formed by similar or the same processes; therefore such redundant details are omitted in the interest of brevity. In addition, although FIGS. 1A to 14 are described in relation to the method, it will be appreciated that the structures disclosed in FIGS. 1A to 14 are not limited to the method but may stand alone as structures independent of the method. Similarly, although the methods shown in FIGS. 1A to 14 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a first fin structure and a second fin structure formed over a substrate. The isolation structure is formed over the substrate. The first fin structure includes first nanostructures, and the second fin structure includes second nanostructures along a first direction (e.g. x-axis). A first gate structure formed over the first nanostructures along the second direction (e.g. y-direction) and a second gate structure formed along the second direction (e.g. y-direction). The dielectric strip structure is formed along the second direction (e.g. y-axis), and the dielectric wall structure is parallel with the dielectric strip structure. The dielectric strip structure has protruding portions lower than the bottom surface of the isolation structure. The dielectric wall structure is between the first gate structure and the second gate structure. The dielectric strip structure and the dielectric wall structure are formed by using the same mask, and therefore the fabrication time and cost are reduced.

Furthermore, the dummy gate dielectric layer is between the dielectric wall structure and the first fin structure. Since one side of the nanostructure is in direct contact with the dummy gate dielectric layer, the effective width (W_{eff}) of nanostructure (or channel layer) is reduced. When the effective width (W_{eff}) of nanostructure (or channel layer) is reduced, the current of the semiconductor structure can be reduced for power efficiency. Therefore, the performance of the semiconductor structure is improved.

In some embodiments, a semiconductor structure is provided. The semiconductor structure includes first nanostructures formed over a substrate along a first direction, and second nanostructures formed over the substrate along the first direction. The semiconductor structure includes a first gate structure formed over the first nanostructures along a second direction, and a second gate structure formed over the second nanostructures along the second direction. The semiconductor structure also includes a dielectric wall structure between the first gate structure and the second gate structure along the second direction. The semiconductor structure also includes a dielectric strip structure formed along the second direction. The dielectric strip structure includes a protruding portion which is lower than a bottom surface of a bottommost first nanostructure.

In some embodiments, a semiconductor structure is provided. The semiconductor structure includes a substrate including a first region and a second region. The semiconductor structure includes first nanostructures formed over the substrate along a first direction in the first region and the second region, and second nanostructures formed over the substrate along the first direction in the first region and the second region. The semiconductor structure also includes a dielectric strip structure formed across the first nanostructures and the second nanostructures in the first region. The semiconductor structure includes a dielectric wall structure formed across the first nanostructures and the second nanostructures in the second region. The dielectric wall structure is parallel with the dielectric strip structure, and a bottom surface of the dielectric wall structure is higher than a bottom surface of the dielectric strip structure.

In some embodiments, a method for forming a semiconductor structure is provided. The method includes forming a first fin structure and a second fin structure over a first region and a second region of a substrate, respectively, and the first fin structure includes first semiconductor material layers and second semiconductor material layers alternately stacked, and the second fin structure includes first semiconductor material layers and second semiconductor material layers alternately stacked. The method includes forming a first dummy gate structure and a second dummy gate structure over the first fin structure and the second fin structure in the first region. The method also includes removing a portion of the first dummy gate structure to form a trench in the first region and removing a portion of the second dummy gate structure to form an opening in the second region. The method also includes forming a protection layer in the trench in the first region, and simultaneously forming the protection layer in the opening in the second region to form a dielectric wall structure between the first fin structure and the second fin structure. The method includes removing a portion of the protection layer to expose a portion of the first fin structure and a portion of the second fin structure to form an exposed first fin structure and an exposed second fin structure. The opening is filled with the protection layer after the removing the portion of the protection layer. The method includes removing the exposed first fin structure and the exposed second fin structure to form a recess in the first region. The method includes forming a filling layer into the recess and the trench in the first region to form a dielectric strip structure, and the dielectric strip structure includes the protection layer and the filling layer surrounded by the protection layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first nanostructures formed over a substrate along a first direction;
second nanostructures formed over the substrate along the first direction;
a first gate structure formed over the first nanostructures along a second direction;
a second gate structure formed over the second nanostructures along the second direction;
a dielectric wall structure between the first gate structure and the second gate structure along the second direction; and
a dielectric strip structure formed along the second direction, wherein the dielectric strip structure comprises a protruding portion which is lower than a bottom surface of a bottommost first nanostructure.

2. The semiconductor structure as claimed in claim 1, wherein the dielectric strip structure has a first length along the second direction, the dielectric wall structure has a second length along the second direction, and the first length is greater than the second length.

3. The semiconductor structure as claimed in claim 1, wherein the dielectric wall structure has a top portion which is directly over the first nanostructures.

4. The semiconductor structure as claimed in claim 1, further comprising:
a dielectric layer formed between the dielectric wall structure and the first nanostructures.

5. The semiconductor structure as claimed in claim 1, wherein the dielectric strip structure comprises a first portion and a second portion, wherein the first portion and the second portion are made of different materials.

6. The semiconductor structure as claimed in claim 1, wherein the dielectric wall structure comprises a protruding portion, and the protruding portion is lower than a bottom surface of the bottommost first nanostructure.

7. The semiconductor structure as claimed in claim 1, further comprising:
an isolation structure formed over the substrate, wherein a bottom surface of the isolation structure is higher than a bottom surface of the dielectric strip structure.

8. The semiconductor structure as claimed in claim 1, further comprising:
an S/D structure formed adjacent to the dielectric strip structure, wherein a bottom surface of the S/D structure is higher than a bottom surface of the dielectric strip structure.

9. A semiconductor structure, comprising:
a substrate comprising a first region and a second region;
first nanostructures formed over the substrate along a first direction in the first region and the second region;
second nanostructures formed over the substrate along the first direction in the first region and the second region;
a dielectric strip structure formed across the first nanostructures and the second nanostructures in the first region; and
a dielectric wall structure formed across the first nanostructures and the second nanostructures in the second region, wherein the dielectric wall structure is parallel with the dielectric strip structure, and a bottom surface of the dielectric wall structure is higher than a bottom surface of the dielectric strip structure.

10. The semiconductor structure as claimed in claim 9, wherein the dielectric wall structure has a first surface and a second surface, the first surface is in direct contact with a first gate structure, and the second surface is in direct contact with a second gate structure.

11. The semiconductor structure as claimed in claim 9, further comprising:
an isolation structure formed over the substrate, wherein the isolation structure is in direct contact with the dielectric strip structure.

12. The semiconductor structure as claimed in claim 9, wherein the dielectric strip structure has a first length along the second direction, the dielectric wall structure has a second length along the second direction, and the first length is greater than the second length.

13. The semiconductor structure as claimed in claim 9, wherein the dielectric wall structure has a top portion which is directly over the first nanostructures.

14. The semiconductor structure as claimed in claim 9, wherein the dielectric strip structure comprises a first portion and a second portion, and the first portion and the second portion are made of different materials.

15. A method for forming a semiconductor structure, comprising:
forming a first fin structure and a second fin structure over a first region and a second region of a substrate, respectively, wherein the first fin structure comprises first semiconductor material layers and second semiconductor material layers alternately stacked, and the second fin structure comprises first semiconductor material layers and second semiconductor material layers alternately stacked;
forming a first dummy gate structure and a second dummy gate structure over the first fin structure and the second fin structure in the first region;
removing a portion of the first dummy gate structure to form a trench in the first region and removing a portion of the second dummy gate structure to form an opening in the second region;
forming a protection layer in the trench in the first region;
simultaneously forming the protection layer in the opening in the second region to form a dielectric wall structure between the first fin structure and the second fin structure;
removing a portion of the protection layer to expose a portion of the first fin structure and a portion of the second fin structure to form an exposed first fin structure and an exposed second fin structure, wherein the opening is filled with the protection layer after the removing the portion of the protection layer;
removing the exposed first fin structure and the exposed second fin structure to form a recess in the first region; and
forming a filling layer into the recess and the trench in the first region to form a dielectric strip structure, wherein the dielectric strip structure comprises the protection layer and the filling layer surrounded by the protection layer.

16. The method for forming the semiconductor structure as claimed in claim 15, further comprising:
forming an isolation structure over the substrate, wherein the first fin structure and the second fin structure extend above the isolation structure; and
removing a portion of the isolation structure when removing the portion of the second dummy gate structure to form the opening, so that the opening has a protruding portion, wherein the protruding portion is lower than a top surface of the isolation structure.

17. The method for forming the semiconductor structure as claimed in claim 15, wherein the opening is still filled with the protection layer after removing the exposed first fin structure and the exposed second fin structure to form the recess in the first region.

18. The method for forming the semiconductor structure as claimed in claim 15, further comprising:
forming a first S/D structure adjacent to the first dummy gate structure, wherein a bottom surface of the first S/D structure is higher than a bottom surface of the dielectric strip structure.

19. The method for forming the semiconductor structure as claimed in claim 15, wherein the first dummy gate structure comprises a dummy gate dielectric layer and a dummy gate electrode formed over the dummy gate dielectric layer, and the dummy gate dielectric layer is in direct contact with the dielectric wall structure.

20. The method for forming the semiconductor structure as claimed in claim 15, further comprising:
forming an isolation structure over the substrate, wherein the first fin structure and the second fin structure extend above the isolation structure, and a bottom surface of the isolation structure is higher than a bottom surface of the dielectric strip structure.
